(19) United States
(12) Patent Application Publication
(10) Pub. No.: US 2022/0417669 A1
(43) Pub. Date: Dec. 29, 2022

(54) GRAPHENE TRANSDUCERS

(71) Applicant: GRAPHAUDIO INC., Beverly Hills, CA (US)

(72) Inventors: Burt FOWLER, Buda, TX (US); David CAYLL, Sugar Land, TX (US); YuanJun FAN, Austin, TX (US); James Wyatt ECKSTROM, Austin, TX (US); Lorance WILSON, San Jose, CA (US)

(21) Appl. No.: 17/780,242

(22) PCT Filed: Nov. 24, 2020
(86) PCT No.: PCT/US2020/061957

§ 371 Date: May 26, 2022

Related U.S. Application Data
(60) Provisional application No. 62/940,516, filed on Nov. 26, 2019.
(60) Provisional application No. 63/064,062, filed on Aug. 11, 2020.

(51) Int. Cl. H04R 19/01; H04R 31/00; H04R 7/10; H04R 19/00; H04R 1/40

(52) U.S. Cl. CPC H04R 19/01; H04R 31/003; H04R 7/10; H04R 19/005; H04R 1/40; H04R 2307/023; H04R 2201/003; H04R 2201/401

(57) ABSTRACT

The present application relates to graphene-based transducing devices, including micromechanical ultrasonic transducers and electret transducers. A micromachined ultrasonic transducer comprising: a backing layer, a spacer layer, and a diaphragm comprising a material selected from the group consisting of graphene, h-BN, MoS2, and combinations thereof, wherein the backing layer comprises a first etched semiconductor, glass, or polymer, wherein the spacer layer comprises a second etched semiconductor, glass, or polymer.

### INCORPORATION BY REFERENCE OF RELATED PATENT APPLICATIONS

This application is based upon and claims priority under 35 U.S.C. § 119(e) to U.S. provisional application U.S. Ser. No. 62/940,516 filed Nov. 26, 2019, and U.S. provisional application U.S. Ser. No. 63/064,062 filed Aug. 11, 2020, the entire contents of all of which are incorporated herein by reference in their entirety.

### FIELD OF THE INVENTION

The present application relates to graphene-based transducing devices, including micromechanical ultrasonic transducers and electret transducers. Exemplary embodiments of the present application provide exemplary devices, circuits for incorporation in such devices, and methods of making and using such devices.

### BACKGROUND

Transducers convert energy from one form into another. A familiar transducing device is a loudspeaker, which converts electrical energy into acoustic energy. Thus, it is possible to represent a series of sounds as electrical signals, which signals are converted by a loudspeaker into sound by parts of the loudspeaker that are made to vibrate at different frequencies corresponding to the electrical signals. A microphone is another transducing device that converts acoustic energy into electrical energy. As sound waves cause certain components in the microphone to vibrate, the microphone produces electrical signals. These signals can be analyzed or stored for later playback on the loudspeaker

Acoustic energy is transmitted in the form of waves. Such waves can propagate through matter, such as gas particles in the air, before arriving at a transducing device. Depending on the frequency of the waves, the acoustic energy may be audible or inaudible to humans, who can only perceive sound waves having frequencies between approximately 20 Hz and 20 kHz, i.e. within the audible range. Sound waves having frequencies above this range, i.e. greater than 20 kHz, are known as ultrasound, and are said to be “ultrasonic.” Sound waves having frequencies below this range, i.e. less than 20 Hz, are known as infrasound, and are said to be infrasonic.

One important aspect of a transducing device is how the device produces or measures sound vibration. In dynamic systems, a conductor (e.g. a coil of wire) is connected to a diaphragm and placed inside a permanent magnetic field. Dynamic speakers produce sound by passing an alternating current through the conductor to vibrate the diaphragm, and dynamic microphones record sound by measuring current produced in the conductor when the diaphragm vibrates from incoming sound. By contrast, in electrostatic systems, a conductor is connected to a diaphragm placed inside a permanent electric field. Electrostatic speakers produce sound by passing an alternating current through the diaphragm or through components producing the electric field, and electrostatic microphones record sound by measuring the current produced when the diaphragm vibrates.

Condenser (or capacitor) microphones, and electret condenser microphones (ECM) are types of electrostatic transducing devices. Condenser microphones and ECMs provide immense utility in a variety of applications in research and industry including the following: electronics, commercial audio technology, studio sound recording, and gas ion detectors. The sensing/transducing elements of a condenser microphone typically comprises a diaphragm—or membrane—typically made from Polyethylene Terephthalate (PET) coated with thin layer of conductive material, a fixed back plate electrode, and a standoff perimeter-lining insulator to form a capacitive gap between the aforementioned elements. The dielectric air-gap is characteristic of this design, and together, form a microphone capsule.

Common among all microphones is a biasing voltage across the dielectric gap between the electrode and diaphragm. With some pressure incident on the diaphragm, the voltage changes proportionally with the ratio of displacement δ(t) to d₀, the equilibrium spacing, at the same frequencies as the incoming sound wave. This AC signal is used to interpret the nature of incoming sound as it interacts with the diaphragm. In condenser microphones, a DC power source is needed for biasing the variable capacitor while ECM platforms use electrets to self-bias. Pure condenser microphones receive external power as a polarizing voltage, supplied typically by battery or phantom power. ECMs are different from pure condenser microphones in that they use electret layer(s) to serve as the biasing potential, which lasts throughout the product's lifetime and thus consumes less power. Since ECM microphones require less power to operate, they are generally more convenient and efficient for many different contexts. Among the benefits granted to electret condenser designs are lightweight portable assemblies, enhanced frequency pick-up range, size miniaturization, and uniform frequency responses.

Electret charge layers, typically made of Teflon but can be some other charged dielectric such as PMMA, Quartz or other materials that provide quasi-permanent potential when charged with electret charging methods. The charging is facilitated through space charges, surface charges, aligned dipole moments, or some combination of those depending on charging methodology. Historically, electret films are used in microphones and applied as another layer on the diaphragm, also known as a foil type ECM. Eventually, the electret was moved to the electrode to shed weight from the diaphragm, thus improving the microphone performance. This has since become the standard configuration of ECMs. In terms of manufacturing, electret microphones can be produced at high volume with good, repeatable performance across devices.

Electrostatic loudspeakers and condenser microphones share many structural similarities due to similar operating principles; therefore, the same structural elements which produce sound can also capture sound if the underlying electronics are reconfigured. Electrostatic loudspeakers may be open-faced, meaning only a single electrode is required or push-pull configuration with a second electrode equally distant and on the opposite side of the diaphragm. Both configurations can accommodate electrets as diaphragm-adhered or electrode-adhered layers. In the push-pull loud speaker configuration, the second stator serves to equalize the electrostatic forces normal to the diaphragm accommodating for the non-linearity of a single electrode; the conducting membrane has an applied DC bias voltage while the two perforated stators carry the AC signal.

While electrostatic loudspeakers and microphones generally possess superior acoustic properties as compared to dynamic systems, they also come with important drawbacks. In particular, the bias voltages used in most commercial electrostatic loudspeakers are in the thousands of volts, with headphone products being in the hundreds of volts. Because portable batteries deliver voltage potentials much lower (e.g., up to 12 volts), portable electrostatic devices require bulky and impractical amplifiers with relatively complex circuitry. This requirement limits usership amongst mainstream audio consumers. Accordingly, there is a need to lower the operating voltages required to operate electrostatic devices.

The inventors of the present application have developed a graphene electrostatic transducer which addresses the foregoing. In particular, the transducers according to the present application utilize a graphene electret approach, which delivers higher quality audio than current technology and lowers the voltages required to drive the transducing device.

As to ultrasonic devices specifically, transducer designs have evolved, with the prevalent state-of-the-art technology employing piezoelectric ceramics, such as lead zirconate titanate (PZT) mounted in arrays and integrated with advanced polymer materials. Piezo-based technologies produce narrowband transducing devices that operate only within narrow and discrete ultrasonic frequency ranges dictated by device geometry. The conventional piezo-based approach uses electrical stimulation to induce mechanical vibrations at the resonant frequency of the piezoelectric crystal. In such a system an electrical potential may be applied across two metallic electrodes causing the piezo-material to expand and contract at its natural resonance frequency based on rapid reorientation of electric dipoles within the PZT. An example of a traditional PZT-based device is depicted in FIG. 1. The device (10) includes a housing (11) containing a bottom electrode (12), a top electrode (13), and a piezoelectric material (14). Behind the bottom electrode (12) is a backing material (15). Above the top electrode are one or more impedance matching layers (15, 16). Finally, the PZT-based device includes an acoustic lens and protective polymer (17, 18).

In practice, a piezo-based system therefore includes multiple PZT transducers, each designed to resonate at a particular target frequency. Such arrays are generally prepared by sawing PZT materials, as shown in FIG. 2. Fabrication begins with bulk PZT material (20), which is diced to create multiple first cuts (21). The material (20) is diced in a direction orthogonal to the first cuts (21) to create multiple second cuts (22). The first cuts (21) and second cuts (22) form diced posts (23). The space created by the cuts (21, 22) is filled with epoxy or other suitable material, and the bottom of the PZT material (20) is then lapped to create a PZT array (25). Because system size, weight, and power scale with the number of frequencies, a piezo-based system is limited to only a small number of available frequencies.

Traditional PZT transducer technology is very mature, and is currently the primary choice for most ultrasonic sensors. More recently, however, transducers using suspended diaphragms in the form of a capacitive micromachined ultrasonic transducer (CMUT) or a piezoelectric micromachined ultrasonic transducer (PMUT) have been introduced. An exemplary CMUT cross-section is shown in FIG. 3. The device (30) includes electrodes (31, 32) and a membrane (33) made of silicon. The membrane (33) can deflect (34) into a cavity (35) bounded by the membrane (33) and an insulating layer (36) by applying a combination of an AC voltage and DC voltage to the electrodes (31, 32) and membrane (33). The device (30) is fabricated on a silicon substrate (37).

An exemplary PMUT cross section is shown in FIG. 4. The device (40) includes electrodes (41, 42) and a piezoelectric layer (43). Below the electrode (42) is a layer of SiO₂ (44). The device (40) produces sound based on the flexural motion of the SiO₂ layer (44), which is coupled to the piezoelectric layer (43). The SiO₂ layer (44) can deflect (45) into a cavity (46) bounded by the SiO₂ layer (44) and a silicon substrate (46).

Together, these devices are generally known as micromachined ultrasonic transducers (MUTs).

MUTs offer several advantages over traditional bulk PZT transducer technology, including the ability to be directly integrated into traditional BJT and CMOS integrated circuit technologies and produced using existing semiconductor-based manufacturing equipment, infrastructure and technology platforms. The generally small transducer size required for ultrasonic frequencies and the mature microfabrication infrastructure combine to provide economies of scale benefits similar to those driving the semiconductor manufacturing industry, where a single 8″-diameter substrate for example could yield several thousands of CMUT devices, leading to low-cost, high-volume manufacturing.

The typical sizes of MUTs also allow a single device to incorporate many individual transducers, often arranged in an array. This configuration permits an array-style MUTs to be tuned to a much larger number of frequencies than possible when using bulk PZT-based technologies. In this way, a MUT is like an 88-key grand piano, able to produce (and detect) greater variety of ultrasonic frequencies, whereas bulk PZT is like a child's 4-key piano, able to produce (and detect) a relatively limited set of sounds.

Furthermore, CMUT transducers typically exhibit single-frequency linewidths (typically the full width at half maximum) of their audio spectrum that are inherently much narrower than bulk piezo-based devices, meaning that substantially more information can be transmitted and received within a given passband, thus leading directly to improved communications encryption for example, higher-resolution images in medical applications, and the general ability to produce higher-power-density signals.

The passband of each device is fundamentally limited by MUT size. When manufactured in an array format, device size can be varied across the array if desired to provide multiple frequency profiles and a larger total system bandwidth. The high-impedance nature of capacitance-based CMUTs leads directly to low power requirements suitable for array formats. CMUT technology can also be used in a ‘coherent focal plane array’ configuration, where all transmit/receive signals from all elements within the array are phased-matched to achieve coherency.

Thus, MUTs offer several advantages as compared to bulk piezo-based approaches.

MUTs are produced using MEMS-style surface micromachining manufacturing approaches, with each individual suspension in a MUT being less than about 500 um in diameter. These devices typically operate in the 1-40 MHz range, and can be tuned to a variety of frequencies by modifying device dimensions and/or diaphragm properties. Because of their higher frequency operating ranges, MUTs are not suited for many ultrasonic applications, however, such as SONAR, which require lower ultrasonic frequencies. Instead, MUTs are generally used for short-range, high-resolution imaging applications such as medical imaging, microscopy, inkjet printing, non-destructive testing, gesture detection and fingerprint reading. Like traditional piezo-based transducers, MUTs also exhibit a narrow resonator-like response because their structures promote sharp resonance curves. FIG. 5 shows a frequency response curve for a traditional CMUT device showing how frequency response changes with diaphragm diameter. PMUTs exhibit similar response curves, meaning both classes of devices function essentially as resonators with resonance frequency tunable based on device materials properties and diameter sizing. However, a well-known downside to PMUT technology, particularly in array configurations, is their large power dissipation and related heating issues. Accordingly, for many applications, MUTs must be used in an array configuration having multiple MUT transducers where circumstances require transmission or detection across multiple frequencies.

Thus, while MUTs offer advantages over traditional piezo-based bulk devices in certain applications, they nevertheless still exhibit many of the same drawbacks, and further are not capable of all types of ultrasonic sensing. Without the ability to produce wideband transmission, both traditional bulk piezo-based devices and MUTs must be engineered for each desired application and must utilize arrays of transducers to achieve a response across multiple frequencies. Even in arrays, these configurations are not truly wideband, because they only function across a set of frequencies rather than a broad ultrasonic range. Furthermore, the array required for response across multiple frequencies is energy and resource inefficient and is otherwise costly to produce and operate.

Ultrasonic technology is being incorporated into an ever-increasing number of modern systems. To accommodate the diverse engineering requirements across these disparate systems, there is a need for a wide-band ultrasonic transmitter and receiver which possesses the advantages of a MUT, but which also can produce a wideband response in the ultrasonic (and potentially audible) range without resorting to an array configuration.

### SUMMARY

A graphene-based diaphragm, with its low mass, high elastic modulus, excellent carrier mobility, and chemical inertness, is desirable for acoustic performance over comparable materials. This application in part relates to graphene diaphragms in electret-enabled acoustics applications. An electret enabled microphone or speaker with a two-dimensional graphene diaphragm is self-biasing while providing superior performance. This is because the thinness and strength of the graphene film allows adding an electret film as a complimentary hybrid film stack with significantly less mass than other films such as PET. By utilizing a diaphragm- or electrode-adhered electret film (which provides the high bias voltage requirement of electrostatic speaker designs), the embodiments of the present application enable more efficient and space saving electronic drivers to help usher in a new era of loudspeakers.

The electret material used according the application is an inherent insulator/dielectric capable of maintaining a permanent charge that produces electric fields. These charges may take the form of surface charges, space charges within at any distance from the surface of the material, or permanently oriented dipoles. For the present application, many different electret materials could be used, including fluoropolymers, silicon-based insulators, or any other type of dipole containing polymer.

An embodiment of a graphene electret transducer according to the present application contains a graphene diaphragm suspended a ring of a conductive material such as copper, brass, or other similar material. The ring can be any shape (such as square, rectangular, or other complex shapes such as ovals and kidney shapes), wherein the graphene diaphragm geometry will match the shape of the ring. In general, the diameter of the graphene diaphragm is intended to fall within 3-9, 9-18, 18-30, or 30-50 mm, depending on overarching geometry and application. The diaphragms consist of 60 nm to 120 nm of graphene thickness with the addition of 60 nm to 180 nm of electret film. These films are much thinner and compliant than what is conventionally possible in normal devices that use Mylar or PET films, which are typically 2 pm to 6 pm. The graphene diaphragms can be more successfully scaled down than Mylar or PET diaphragms since stiffness and compliance can be tuned to manage viscous damping according to specific acoustic needs of the system. The electret film then functions as a mechanical support layer for preventing diaphragm damage and maintaining its integrity.

In an embodiment according to the present application, the diaphragm with electret material suspended on the edge ring will have a dielectric spacer separating it from one or more electrodes. The dielectric spacer may be nylon, PET, mylar, or polycarbonate, for example. The dielectric spacers are employed to prevent the diaphragm from shorting on the conducting electrode and for establishing an airgap for diaphragm modulation. The electrodes are also made from brass, copper, aluminum, or other conducting material or may be a composite material such as FR4 with a copper electrode plane on it. If one chooses a more conventional configuration of moving the electret film to coat the electrode, this would be structurally permitted.

In general, the electrostatic forces are non-linear with electrode spacing, thus smaller gaps result in more efficient transducers. Smaller drivers and smaller gaps also generally enable ultrasonic applications. A push/pull configuration can be used to overcome non-linearity in electrostatic force. In some configurations, larger gaps may be necessary due to larger displacements at either end of diaphragm excursion, especially in the lower frequency range. The addition of an electret material is particularly advantageous as it introduces a self-bias that would normally require a DC power supply. In this way, the graphene electret transducers according to the present application consume less power, therefore simplifying driver electronics. It is possible to apply the electret material to the diaphragm or the electrodes.

The inventors of the present application have also invented novel MUTs which utilize two-dimensional materials, and in particular graphene-based transducers, to produce a wideband ultrasonic response within an MUT-like platform. Such devices are able to produce a wideband response with just a single transducer. Accordingly, arrays of such graphene-based MUTs are not required for a wideband response, and when arrays of such graphene-based MUTs are provided, the array may be configured for other purposes, such as increasing power output or transmitting/receiving signals with unique directionality properties.

Thus, in one aspect, the present application provides a graphene MUT, which the inventors of the present application will refer to in some circumstances as a GMUT (“graphene micromechanical ultrasonic transducer”). In some embodiments, a GMUT would have a design similar to a CMUT or PMUT. For example, in some embodiments, a GMUT would include a housing and a backing material. In some embodiments, a GMUT would include a bottom electrode and/or a top electrode. In some embodiments, a GMUT would include one or more impedance matching layers. In some embodiments, a GMUT would include an acoustic lens and a protective polymer.

In some embodiments, a GMUT includes a silicon or glass substrate. In some embodiments, the GMUT could have a second electrode to operate in push/pull mode in order to achieve higher efficiency and better sensitivity (diaphragm deflection/volt) much like a traditional electrostatic transducer. Importantly, based on the physical properties of graphene, a GMUT configured either as a single- or dual-stator device has significant advantages over standard piezo-based and MUT transducers because of the wideband capability, extremely low mass and high strength per weight of graphene.

In another aspect, the present application provides graphene micromachined ultrasonic transducer comprising a backing layer, a spacer layer, and a graphene diaphragm, wherein the backing layer comprises a first etched semiconductor or glass, wherein the spacer layer comprises a second etched semiconductor or glass. In another aspect, the backing layer further comprises an electrode layer deposited on (a) the first etched semiconductor or glass or (b) an oxide layer deposited on the first etched semiconductor or glass. In another aspect, the electrode layer comprises a material selected from the group consisting of copper, platinum, gold, iridium, tungsten, titanium, silver, palladium, metal alloys (TiW, TiN etc.), doped silicon, metal silicides (NiSi, PtSi, TiSi2, WSi2 etc.), indium tin oxide (ITO), fluorene doped tin oxide (FTO), doped zinc oxide, poly(3,4-ethylenedioxythiphene) (PEDOT) and its derivatives, carbon nanotubes, graphene, graphite, or conductive or semiconductive carbon. In another aspect, the spacer layer further comprises a conductive layer deposited on (a) the second etched semiconductor or glass or (b) an oxide layer deposited on the second etched semiconductor or glass. In another aspect, the electrode layer comprises a material selected from the group consisting of copper, platinum, gold, iridium, tungsten, titanium, silver, palladium, metal alloys (TiW, TiN etc.), doped silicon, metal silicides (NiSi, PtSi, TiSi2, WSi2 etc.), indium tin oxide (ITO), fluorene doped tin oxide (FTO), doped zinc oxide, poly(3,4-ethylenedioxythiphene) (PEDOT) and its derivatives, carbon nanotubes, graphene, graphite, or conductive or semiconductive carbon.

In another aspect, the present application provides a graphene micromachined ultrasonic transducer a second spacer layer and a top layer, wherein the second spacer layer comprises a third etched semiconductor or glass, wherein the top layer comprises a fourth etched semiconductor or glass. In another aspect, the backing layer or the top layer comprise acoustic holes extending through the entire backing layer or top layer. In a further aspect, the graphene micromachined ultrasonic transducer has an acoustic matching material arranged over the acoustic holes to seal the device. In another aspect, the acoustic matching material comprises graphene.

In another aspect, the present application provides a method of manufacturing a graphene micromachined ultrasonic transducer, the method comprising: providing a first silicon wafer, providing a first oxide layer on the first silicon wafer, providing a first conductive layer on the first oxide layer or the first silicon wafer, etching the first silicon wafer to create holes through the first silicon wafer, the first oxide layer, and the first conductive layer, providing a second silicon wafer, providing a second oxide layer on the second silicon wafer, providing a second conductive layer on the second silicon wafer or the second oxide layer, etching the second silicon wafer to create a hole through the second silicon wafer, the second oxide layer, and the second conductive later, and permanently joining the etched first silicon wafer, the etched second silicon wafer, and a graphene diaphragm. In another aspect, the method includes providing a third silicon wafer, providing a third oxide layer on the third silicon wafer, etching the third silicon wafer to create holes through the third silicon wafer and the third oxide layer, providing a fourth silicon wafer, providing a fourth oxide layer on the fourth silicon wafer, etching the fourth silicon wafer to create a hole through the fourth silicon wafer, and the fourth oxide layer, and permanently joining the etched first silicon wafer, the etched second silicon wafer, the graphene diaphragm, the etched fourth silicon wafer, and the etched third silicon wafer. In another aspect, the graphene diaphragm is electrically connected to the second conductive layer. In another aspect, the graphene diaphragm is electrically connected to the second conductive layer. In another aspect, the method includes providing a third conductive layer on the third oxide layer or the third silicon wafer.

In another aspect, the application provides, a method of operating a graphene micromachined ultrasonic transducer, the method comprising providing a graphene micromachined ultrasonic transducer comprising a backing layer, a spacer layer, and a graphene diaphragm, and generating an electric field sufficient to move the graphene diaphragm into physical contact with the backing layer. In another aspect, the backing layer comprises an electrode with an insulating layer preventing the graphene diaphragm and the electrode from creating a short circuit when the graphene diaphragm moves into physical contact with the backing layer. In another aspect, the method includes operating graphene micromachined ultrasonic transducer while keeping the center of the graphene diaphragm touching the insulating layer. In another aspect, the method includes operating the graphene micromachined ultrasonic transducer in a manner involving the graphene diaphragm touching the insulating layer and then releasing such that the graphene diaphragm is not touching the insulating layer.

In another aspect, the application provides an array of transducers comprising a plurality of graphene micromachined ultrasonic transducers, each graphene micromachined ultrasonic transducer comprising a backing layer, a spacer layer, and a graphene diaphragm, and metallic interconnects connecting each graphene micromachined ultrasonic transducer to processing circuitry configured to drive or detect a response in each graphene micromachined ultrasonic transducer. In another aspect, the graphene micromachined ultrasonic transducers are electrically addressed together (i.e., they are all electrically connected). In another aspect, groups of transducers are individually addressed. In another aspect, each of the graphene micromachined ultrasonic transducers is individually addressed. In another aspect, the metallic interconnects between the processing circuitry and the individual transducers have the same wire length, for example to allow high precision beamforming.

As a result of the subject matter of the present application, it is now possible to provide wideband transmission from a single GMUT cell, enabling frequency modulated (FM) transmissions, frequency sweep, spread-spectrum, frequency hopping and other advanced signal modulation methods without need for multiple CMUT cells (where each cell is required to have a different resonant frequency in order to achieve multi-wavelength capability).

The wide bandwidth capability also leads to a GMUT TxRx system with much smaller physical size and weight since each frequency in a PMUT-based or similar discrete-frequency device requires an additional transducer, whereas potentially hundreds of thousands of frequencies are available from a single GMUT transducer cell. With approximately the same sized cell, a GMUT can extend to much lower ultrasonic frequencies while also covering frequencies well above current CMUT and PMUT capabilities. In addition, array configurations typically used in CMUT and PMUT devices to achieve broader frequency response can be implemented in a GMUT device to instead produce much higher power density and beam steering capabilities.

The devices of the present application can be used in diverse technological areas with less engineering and customization required. For example, the GMUTs of the present application can be used in SONAR applications (audio and lower ultrasonic ranges 1-800 kHz), because each GMUT cell can function in these ranges unlike other MUT technologies. In addition, the GMUTs of the present application are also useful in high resolution medical imaging, microscopy, and defect analysis requiring higher ultrasonic frequency ranges of approximately 1-40 MHz, because each GMUT cell can also function in these ranges. GMUTs of the present application are also more effective for certain applications with stringent space requirements. For example, the GMUTs may be used more effectively in small probe catheter applications because they do not need multiple cells to provide different frequencies.

The GMUT devices of the present application also provided better receiving sensitivity with ultra-wideband responsiveness as compared with traditional MUT technology. These GMUTs may be used, for example, as a wideband TxRx device, as a Near Field Communication (NFC) device, or as an NFC/echolocation device for autonomous vehicles or even an audio microphone. The GMUT devices of the present application can also be ruggedized for extreme operating conditions.

It will be understood that elements of the graphene electret transducer embodiments of the present application are compatible with elements of the GMUT devices of the present application. In other words, it will be understood a GMUT device may employ an electret design, and an electret transducer may be a GMUT. Similarly, it will be understood a graphene electret transducer according to the present application may be embodied in a design other than a GMUT, and a GMUT according to the present application need not incorporate an electret design.

Further objects, features, and advantages of the present application will become apparent from the detailed description of preferred embodiments which is set forth below when considered together with the figures and drawings.

### BRIEF DESCRIPTION OF FIGURES OF DRAWING

FIG. 1 depicts a basic traditional PZT transducer probe structure.

FIG. 2 depicts fabrication of a traditional PZT array.

FIG. 3 depicts the cross section of a traditional CMUT device.

FIG. 4 depicts the cross section of a traditional PMUT device.

FIG. 5 depicts a frequency response curve for a traditional CMUT device showing how frequency response changes with diaphragm diameter.

FIG. 6 depicts an exemplary capacitive transducer device using graphene or another ultra-high-strength two-dimensional film.

FIG. 7 depicts circuitry for an exemplary GMUT device.

FIG. 8 depicts exemplary embodiments of collapse-mode architecture.

FIG. 9 depicts an exemplary embodiment of an air dampened device with acoustic vent holes in the back electrode.

FIG. 10 depicts an exemplary embodiment of an air dampened device with a continuous back electrode.

FIG. 11 depicts an exemplary embodiment of an electrostatic push/pull transducer device using graphene or another ultra-high-strength two-dimensional film.

FIG. 12 depicts an exemplary embodiment of a push/pull GMUTe with exterior sealing for high pressure environments.

FIG. 13 depicts another exemplary embodiment of a push/pull GMUTe with exterior sealing for high pressure environments.

FIG. 14 depicts an exemplary embodiment of transmitter and receiver electronics configuration for an open face transducer.

FIG. 15 depicts exemplary graphene transducers produced by inventors of the present application in single and array configurations.

FIG. 16 depicts an exemplary embodiment of a transducer device sealed with dielectric fluid or gas.

FIG. 17 depicts an exemplary embodiment of a coaxial transducer architecture.

FIG. 18 depicts an exemplary embodiment of a phase-matched fractal antenna architecture.

FIG. 19 depicts an exemplary embodiment of a manufacturing method for manufacturing certain embodiments of the present application.

FIG. 20 depicts an exemplary embodiment of another manufacturing method for manufacturing certain embodiments of the present application.

FIG. 21 depicts an exemplary embodiment of an advanced transmission line shielding method for superior signal integrity.

FIG. 22 depicts the cross-section of an exemplary embodiment of a single-sided electret device having a graphene transducer.

FIG. 23 depicts the cross-section of an exemplary embodiment of push-pull (two-sided) electret device having a graphene transducer.

FIG. 24 depicts a perspective view of a push-pull transducing device according to the present application.

FIG. 25 depicts a cross-section of one embodiment of a graphene diaphragm having electret films applied to both surfaces of the diaphragm.

FIG. 26 depicts one way of applying a quasi-permanent electric charge to the embodiment according to FIG. 25.

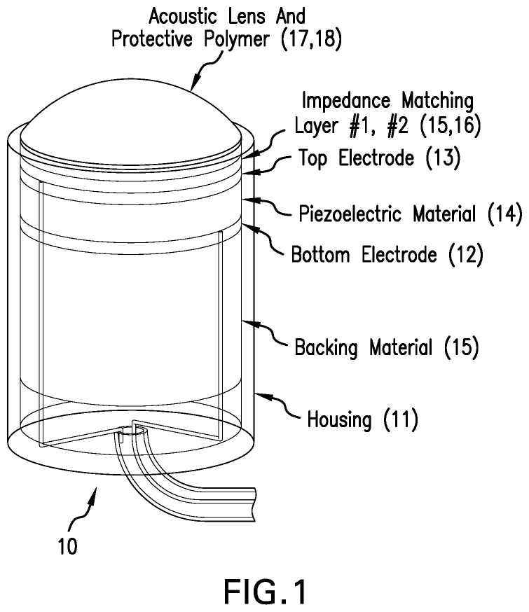

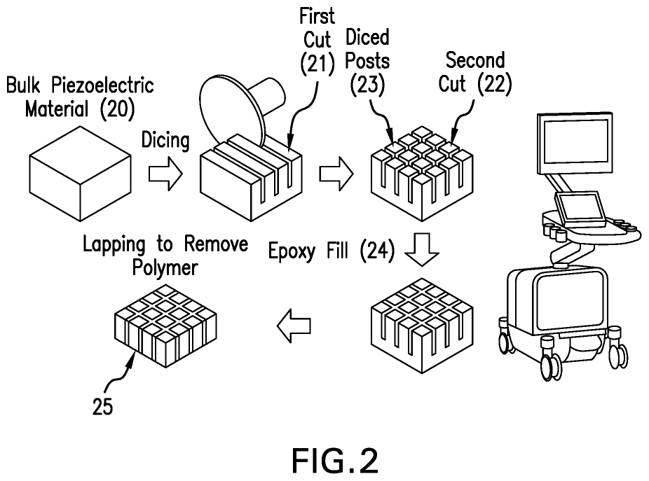

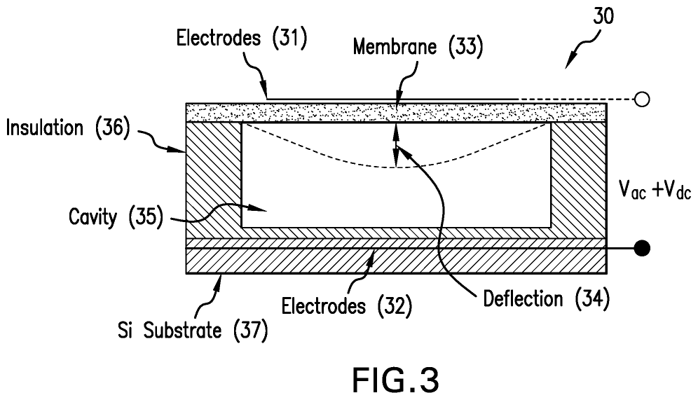

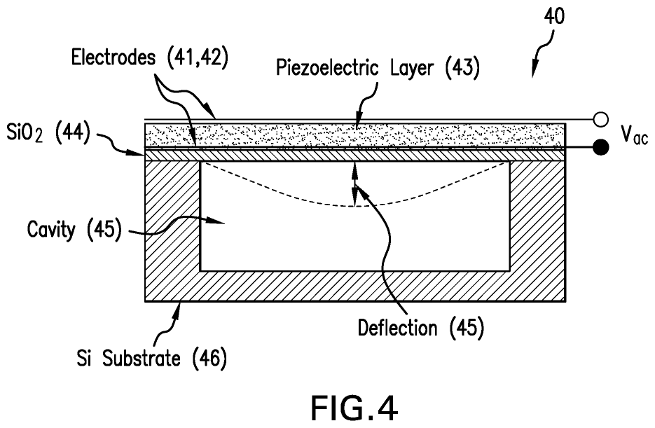

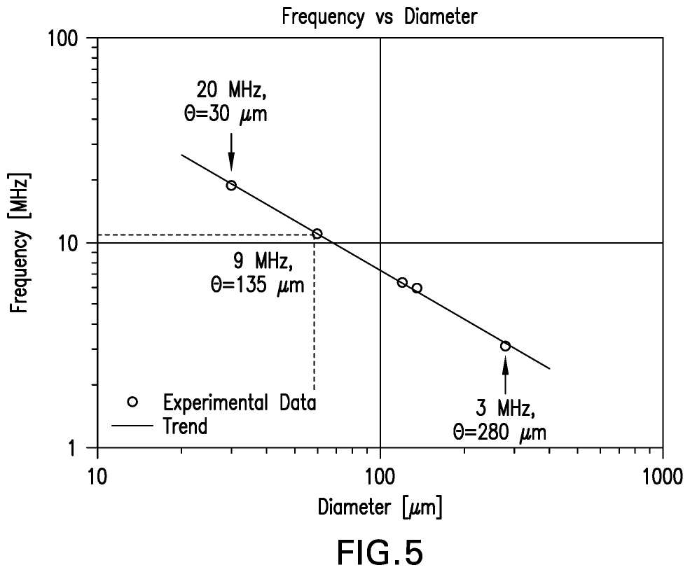

### DETAILED DESCRIPTION OF PREFERRED EMBODIMENTS

The inventors of the present application have invented novel graphene electret transducers (GETs) which utilize two-dimensional materials, and in particular graphene-based transducers, and electret materials, to produce a wideband ultrasonic response with lower power requirements than traditional electrostatic approaches.

The inventors of the present application have also invented novel graphene-based MUTs (GMUTs) which utilize two-dimensional materials, and in particular graphene-based transducers, to produce a wideband ultrasonic response within an MUT-like platform. Unlike traditional CMUTs and PMUTs, GMUTs are able to produce a wideband response with just a single transducer. Accordingly, arrays of GMUTs are not required to produce a wideband response. Thus, when arrays of graphene-based MUTs are provided, the array may be leveraged for other purposes, such as for increasing power output, for recognizing or transmitting signal directionality, or for more complex applications described herein.

It will be understood that elements of the GETs of the present application are intercompatible with the GMUTs of the present application. In other words, it will be understood a GMUT device may employ an electret design, and an electret transducer may be a GMUT. Similarly, it will be understood a graphene electret transducer according to the present application may be embodied in a design other than a GMUT, and a GMUT according to the present application need not incorporate an electret design.

The term “infrasonic” when referring to an acoustic wave means the acoustic wave has a frequency below the human audible range, i.e. below 20 Hz. The term “ultrasonic” when referring to an acoustic wave means the acoustic wave has a frequency above the human audible range, i.e. above 20 kHz. The term “human audible range” or the like when referring to an acoustic wave means the acoustic wave has a frequency within the human audible range, i.e. between 20 Hz and 20 kHz.

The terms “about” or “approximate” and the like are synonymous and are used to indicate that the value modified by the term has an understood range associated with it, where the range can be ±20%, 15%, 10%, 5%, or ±1%. The term “substantially” is used to indicate that a value is close to a targeted value, where close can mean, for example, the value is within 80% of the targeted value, within 85% of the targeted value, within 90% of the targeted value, within 95% of the targeted value, or within 99% of the targeted value.

An acoustic wave may be referred to as a sound wave in various parts of this application, or vice versa.

### GMUT Devices

Thus, in one aspect, the present application provides a graphene MUT, which the inventors of the present application will refer to as a GMUT (“graphene micromechanical ultrasonic transducer”). In some embodiments, a GMUT would have a design similar to a CMUT or PMUT. In some embodiments, the GMUT could have a second electrode to operate in push/pull mode in order to achieve higher efficiency and better sensitivity (diaphragm deflection/volt) much like a traditional electrostatic transducer. Most importantly, based on the physical properties of graphene, a GMUT configured either as a single- or dual-stator device has significant advantages over standard piezo-based and MUT transducers because of the wideband capability, extremely low mass and high strength per weight of graphene.

Before discussing the specific details of certain embodiments of the GMUTs of the present application, the inventors note these embodiments may be modified to include aspects of graphene electret transducers (GETs) discussed in this application.

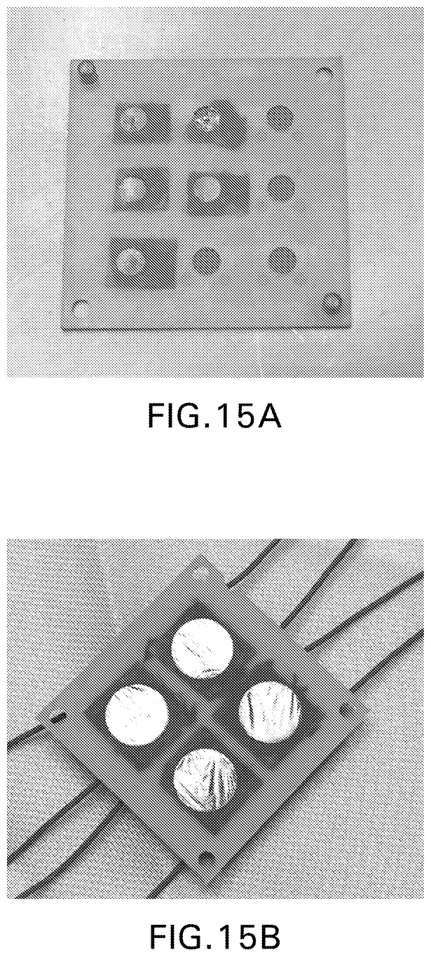

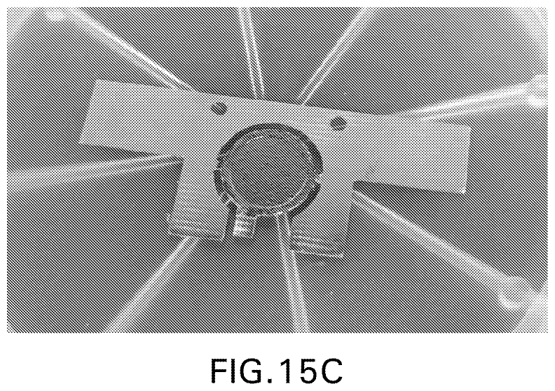

FIG. 15 depicts graphene transducers used in embodiments of the present application which were prepared by the inventors of the present application. These transducers exhibit wideband response in the ultrasonic range. FIG. 15b depicts a simple array configuration of graphene transducers.

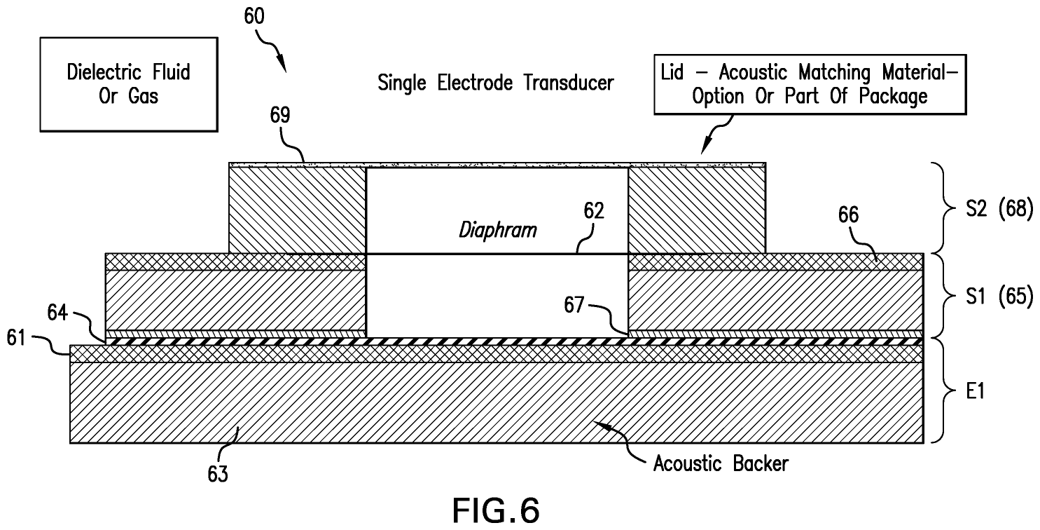

FIG. 6 depicts an exemplary capacitive transducer device (60) using graphene or another ultra-high-strength two-dimensional film according to the present application. The transducer in FIG. 6 includes a single electrode (61), however, a second electrode may be provided on the opposite side of the diaphragm (62). The bottom layer of FIG. 6 is an acoustic backing material (63). The acoustic backing material may include a dielectric material. The dielectric material may be a silicon wafer with an oxidation layer above and/or below the wafer. The dielectric material may also be a glass. Above the dielectric material (63) is an electrode layer (61) made of a conductive material. The conducting material may be a metallized layer, such as copper, platinum, gold, iridium, tungsten, silver, palladium, or other metals, and their alloys. The conducting material may be doped silicon or another doped semiconductor. Such material may also be indium tin oxide (ITO), fluorene doped tin oxide (FTO), doped zinc oxide, and poly(3,4-ethylenedioxythiphene) (PEDOT) and its derivatives. The conducting material may also be a carbon nanotube-based material, a graphene-based material, a graphite-based material, or another conductive or semiconductive carbon-based material. Throughout the application, when referring to electrodes, the inventors noted such electrodes may be made of these materials, or other materials known to a person of ordinary skill in the art. FIG. 6 shows an optional oxide or other dielectric layer (64) above the conducting layer (63). The oxide layer prevents the diaphragm (62) from coming into direct electrical contact with the electrode (63), thus creating a short circuit.

In FIG. 6, above the acoustic backing material, electrode, and dielectric/oxide is a spacer (65). In some embodiments, the spacer includes a dielectric material, such as glass or silicon dioxide. In some embodiments, the spacer includes a semiconducting material, such as silicon. The silicon may be oxidized on a top and/or bottom surface (67). On a portion of the spacer facing the diaphragm (62), the spacer may have a conducting layer (66) to provide an electrical connection to the diaphragm (62). The conducting layer may be made of the same kinds of materials as the electrode layer.

In FIG. 6, above the spacer is a diaphragm (62) comprising a two-dimensional material. In a preferred embodiment, the two-dimensional material comprises graphene. In a preferred embodiment, the two-dimensional diaphragm material is an atomically single or multilayer graphene film (up to thousands of layers of graphene). In another preferred embodiment, the diaphragm is selected from the group consisting of h-BN, MoS2, and a bilayer film comprising the two-dimensional graphene diaphragm material and h-BN, MoS2, or another single or multilayer two-dimensional film.

In FIG. 6, above the graphene diaphragm (62) is another spacer (68). The spacer above the graphene diaphragm (62) may be constructed in a manner similar to the spacer (65) below the graphene diaphragm (62) discussed previously.

In FIG. 6, above the spacer (68) is an acoustic matching material (69), which is optional. The matching material is selected to improve energy transfer between the transducer (60) and the surrounding medium. The matching material may be a material which has an acoustic impedance between the impedance of the transducer and the surrounding medium. The matching layer thus can reduce the energy reflected back toward the transducer by the surrounding medium due to impedance mismatch between the transducer and the surrounding medium.

In another aspect, the application provides a high-quality ultrasonic transducing device which can be operated in transceiver mode over a wide band of ultrasonic and even sonic frequencies. An exemplary embodiment of such a transducing device includes a diaphragm comprising a 2-D material. This diaphragm is mounted to a conducting perimeter which defines an open area for the diaphragm to be suspended over. In some embodiments, the conducting perimeter is embodied as a circle, oval. In other embodiments, the conducting perimeter could have another shape, such as a square, rectangle, star, kidney, n-polygon, or an irregular shape. In several embodiments, the conducting perimeter is referred to as a ring, and it is the intention of the inventors that such discussion refer to any of these shapes.

In an exemplary embodiment, the transducing device includes a spacer for separating the diaphragm and the conducting ring (the diaphragm suspension) from other components, such as an electrode. In one embodiment, the spacer is a layer of dielectric material having an opening in a central region substantially corresponding to the shape of the diaphragm. The spacer is bonded on one side to the conducting ring and to an electrode on the other side. The electrode includes a continuous conducting layer having a side facing toward and substantially parallel to the diaphragm suspension. The transducing device may have a spacer and an electrode on both sides of the diaphragm suspension. If only one electrode is provided, the device is a “single stator” device. If two electrodes are provided, the device is a “dual stator” device. The suspension cavity is the area bounded on its lower and upper sides by the diaphragm and the electrode, and on its periphery by the walls of the opening in the spacer.

In one embodiment, the electrode system can be a thin conducting layer on a stable backing material that will provide rigidity and planarity to the structure. In another embodiment, the electrode system is a thicker sheet of metal which is optionally passivated on one or both of its surfaces (upper or lower). Optionally, a second conducting ring may be added on top of the diaphragm or simply another dielectric spacer installed of comparable thickness as the first spacer. One purpose of such a configuration is to allow the device to have appropriate and/or identical spacing on both sides of the diaphragm to allow the diaphragm to vibrate in an optimal manner.

In some embodiments, the diaphragm optionally has a predefined hole pattern, in which cuts or holes are introduced into the graphene diaphragm. In other embodiments, the graphene diaphragm is continuous. In some embodiments, hole patterns can be utilized to allow free flow and pressure equalization of dielectric fluids. Dielectric fluids can be air or other gases or fluids. In some embodiments, the hole patterns could also be used as a means to adjust acoustic performance. In some embodiments, the diaphragm could be made from graphene or other similar ultra-high strength, low mass 2-dimensional materials such as Hexagonal Boron Nitride (HBN), Molybdenum Disulfide (MoS2), or others.

In some embodiments, in the diaphragm it may be desirable to use a composite graphene structure that includes thin layers of HBN, MoS2 or more conventional materials on one or both sides of the graphene layer to provide additional mechanical strength to the diaphragm, to provide a more-flexible, less-rigid mechanical support along the outer perimeter of the diaphragm, or to create a desired displacement pattern across the diaphragm surface to essentially ‘tune’ or ‘enhance’ the diaphragm's excursion profile in response to applied electrostatic forces. Such patterns would include, for example in a round diaphragm, patterning a disc at the center or a ring with a certain width and radius into the circular diaphragm. Conventional materials that could be used include but are not limited to polymers such as PEEK (Polyether ether ketone), FEP (Fluorinated ethylene propylene) or a wide range of acrylics, polyesters, silicones, polyurethanes, and halogenated plastics. The patterned disc would increase the mass of the diaphragm and reduce its displacement compared to a diaphragm without the patterned disc. Another pattern, the ring for example at the outer edge of the diaphragm would add rigidity to the diaphragm and also reduce its displacement but would enhance its durability. For example, the diaphragm with a patterned ring along its outer perimeter would be able to be driven at higher voltages compared with a diaphragm without a patterned ring.

In some embodiments, a device including a graphene diaphragm can optionally incorporate an acoustic capping layer for sealing the suspension cavity to either further protect the device and or to retain the dielectric fluids. An acoustic capping layer could also comprise graphene.

The embodiments described herein would generally be able to both transmit and receive in a single device from a front side of the device. In such a configuration, an electrode in the device could be mounted to a dampening system or the electrode itself could be a dampener (i.e. made of dampening material) that has been coated to achieve sufficient electrical properties to also act as an electrode. A person of ordinary skill in the art would understand there are many possible configurations of such an electrode/damping system.

The embodiments described herein would also generally be able to both transmit and receive in a single device from both the front and back of the device. In such a configuration, the device could optionally utilize separate microphone transducers (dampened rear electrodes) to discriminate the direction of the incoming signal.

The embodiments described herein can have dimensions comparable to the dimensions of existing CMUT devices, but at any given size the embodiments of the present application will have a much wider operating (frequency) bandwidth as compared to existing CMUT and PMUT devices. Some embodiments of the present application include graphene diaphragms. Some embodiments of the present application include diaphragms having a diameter 50 microns to 500 microns. In certain embodiments, the devices of the present application may be manufactured using MEMS-style formats. The likely size of these devices will be from 10 to 2000 microns.

In one embodiment of the present application, a device for producing ultrasonic transmissions has a relatively small spacer thickness, with the overall gap between the diaphragm and the electrode from 0.25 microns to 300 microns. In such embodiments, the transducer diameter is between approximately 10 microns and 300 microns. In general, in embodiments of the present application, smaller diameter diaphragms require smaller gaps. In ultrasonic devices, the gap is much smaller than gaps used in similar graphene-based audio transmitters (e.g. speakers), because transmission of higher ultrasonic frequencies does not require the same degree of “excursion” or distance of travel within the diaphragm-to-electrode cavity, or gap.

Table I lists some exemplary device parameters for various transducer diameters ranging from 10 um for operation ˜2 MHz to 12,000 um diameter with resonant frequencies ˜1.7 kHz in the audio waveband.

TABLE I
Ultrasonic Transducer Scaling with Diameter

| Diameter: | 10 um | 100 um | 1000 um | 4000 um | 8000 um | 12000 um | Units |
|---|---|---|---|---|---|---|---|
| Gap | 0.25 | 2.5 | 25 | 100 | 200 | 300 | um |
| Hole | 0.125 | 1.25 | 12.5 | 50 | 100 | 150 | um |
| Bias Voltage | 0.25 | 2.5 | 25 | 100 | 200 | 300 | V |
| Resonance Freq | 2000 | 200 | 20 | 5 | 2.5 | 1.7 | kHz |

It should be noted that in some embodiments, operation of the GMUT transducers is below the first resonant mode to maximize bandwidth and linearity. However, in some embodiments the GMUT may be operated at the resonant frequency or above to increase output levels.

In the embodiments of the present application, the gap size and operating voltages determine the magnitude and direction of electric field between electrodes and diaphragm. In some embodiments, the electric field is approximately 1 V/um. Smaller gaps permit application of larger magnitude electric fields, which in turn apply a higher force to a charged diaphragm. As a result, smaller gaps may produce a higher acoustic output for a given voltage input. In some embodiments of the present application, it is expected a device having a graphene diaphragm will function from 0.25 VDC to 1000 VDC, with 2 VAC to 650 VAC RMS signal voltages at nominal gaps of 100-200 microns. Other gap settings are possible in each device, and voltage parameters and frequency can be adjusted in any device to tune the device for optimal audio or ultrasonic performance.

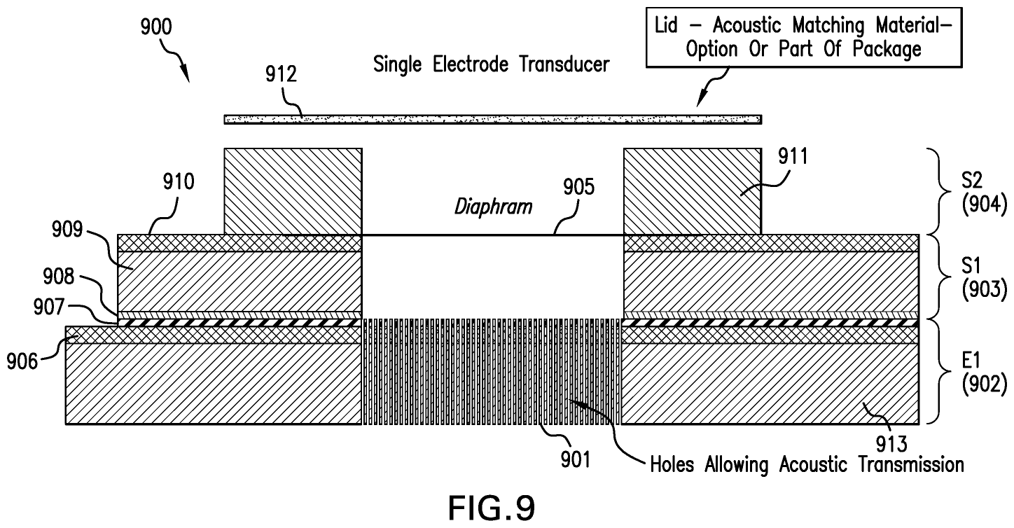

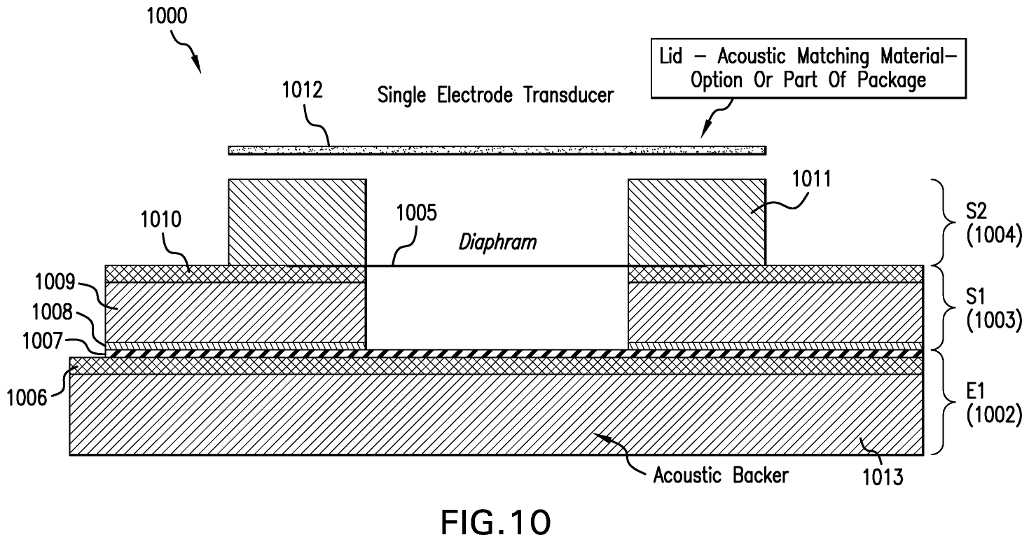

In another embodiment of the present application, the device optionally includes fluid or air dampening. Fluid or air-dampening is optional and FIGS. 9 and 10 show such a device having a single electrode configuration. In particular, FIG. 9 includes a device having acoustic vent holes to allow improved transmittal of energy through the electrode or backside of the device. Specifically, FIG. 9 depicts an exemplary embodiment of an air dampened device (900) with acoustic vent holes (901) in the back electrode. The device (900) includes an electrode layer (902), a first spacer layer (903), a second spacer layer (904), and a diaphragm (905). The first electrode layer (902) includes an acoustic backing material/dielectric layer (913), a conductive layer (906) (forming an electrode), and an oxide or dielectric layer (907). The conductive layer (906) continues across the entire electrode layer (902), and has vent holes (901) throughout. The first spacer layer (903) includes an optional oxidized surface layer (908), a dielectric layer (909), and a conductor layer (910) (which is electrically connected to the diaphragm (905)). The second spacer layer (904) includes a dielectric layer (911). The device (900) also includes an optional acoustic matching material/lid (912). Each of the foregoing layers may be made of the materials previously described in the application.

FIG. 10 depicts an exemplary embodiment of an air dampened device (1000) with a continuous back electrode. The device (1000) includes an electrode layer (1002), a first spacer layer (1003), a second spacer layer (1004), and a diaphragm (1005). The first electrode layer (1002) includes an acoustic backing material/dielectric layer (1013), a conductive layer (1006) (forming an electrode), and an oxide or dielectric layer (1007). The first spacer layer (1003) includes an optional oxidized surface layer (1008), a dielectric layer (1009), and a conductor layer (1010) (which is electrically connected to the diaphragm (1005)). The second spacer layer (1004) includes a dielectric layer (1011). The device (1000) also includes an optional acoustic matching material/lid (1012). Each of the foregoing layers may be made of the materials previously described in the application. The device (1000) may be surrounded with a dielectric gas or fluid (1018).

Both FIGS. 9 and 10 include an optional acoustic backer below the electrode and an acoustic matching material functioning as a “lid” over the diaphragm.

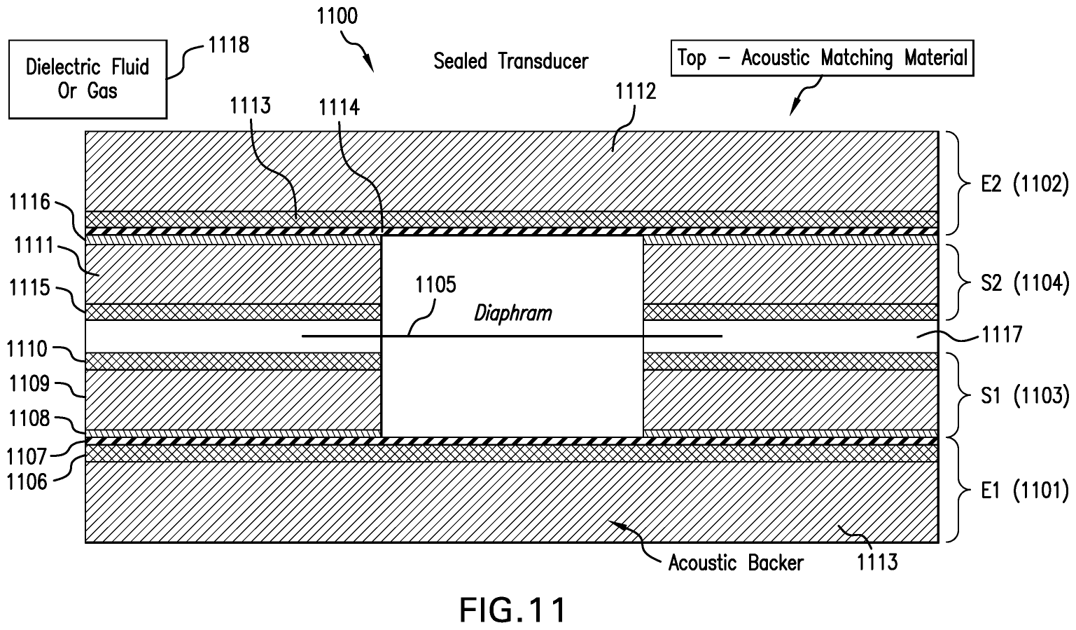

In another embodiment of the present application, the device optionally includes a two electrodes, one above and one below the diaphragm. This configuration permits a more linear pushing and pulling force to be applied to the diaphragm. One exemplary embodiment is shown in FIG. 11. FIG. 11 depicts an exemplary embodiment of an electrostatic push/pull transducer device (1100) using graphene or another ultra-high-strength two-dimensional film. The device (1100) includes a first electrode layer (1101), a second electrode layer (1102), a first spacer layer (1103), a second spacer layer (1104), and a diaphragm (1105). The first electrode layer (1001) includes an acoustic backing material/dielectric layer (1113), a conductive layer (1106) (forming an electrode), and an oxide or dielectric layer (1107). The second electrode layer (1102) includes an acoustic backing material/dielectric layer (1112), a conductive layer (1113) (forming an electrode), and an oxide or dielectric layer (1114). The first spacer layer (1103) includes an optional oxidized surface layer (1108), a dielectric layer (1109), and a conductor layer (1110) (which is electrically connected to the diaphragm (1105)). The second spacer layer (1104) includes an optional oxidized surface layer (1116), a dielectric layer (1111), and a conductor layer (1115) (which is electrically connected to the diaphragm (1105)). It is not necessary to include both conductor layers (1115, 1110). Furthermore, a conductor layer (1117) may be provided independently of the spacer layers (1103, 1104), and in this case, neither conductor layer (1115, 1110) is needed, but instead both are optional. The device (1100) may be surrounded with a dielectric gas or fluid (1118). Each of the foregoing layers may be made of the materials previously described in the application.

The configuration shown in FIG. 11 is similar to a one-sided or “open-face” transducer, e.g. as shown in FIGS. 9 and 10, except that rather than mounting an acoustic lid, a second electrode is provided. This second electrode provides a push/pull configuration typically used in electrostatic transducers. The second electrode can be made of similar materials as the bottom electrode or it can be made of a material of differing acoustic properties to provide differing transmittal properties.

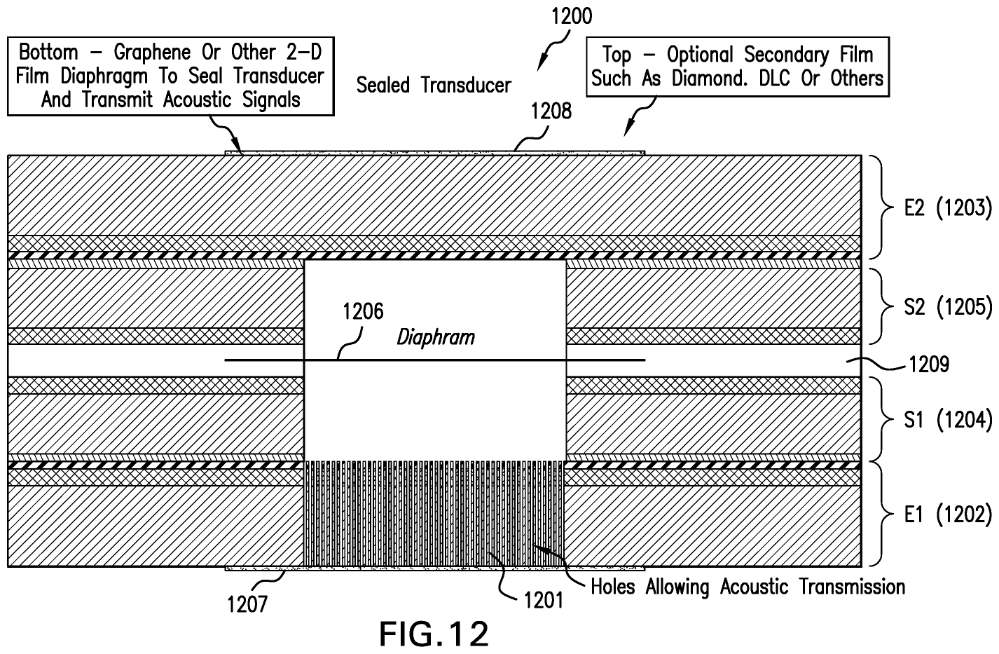

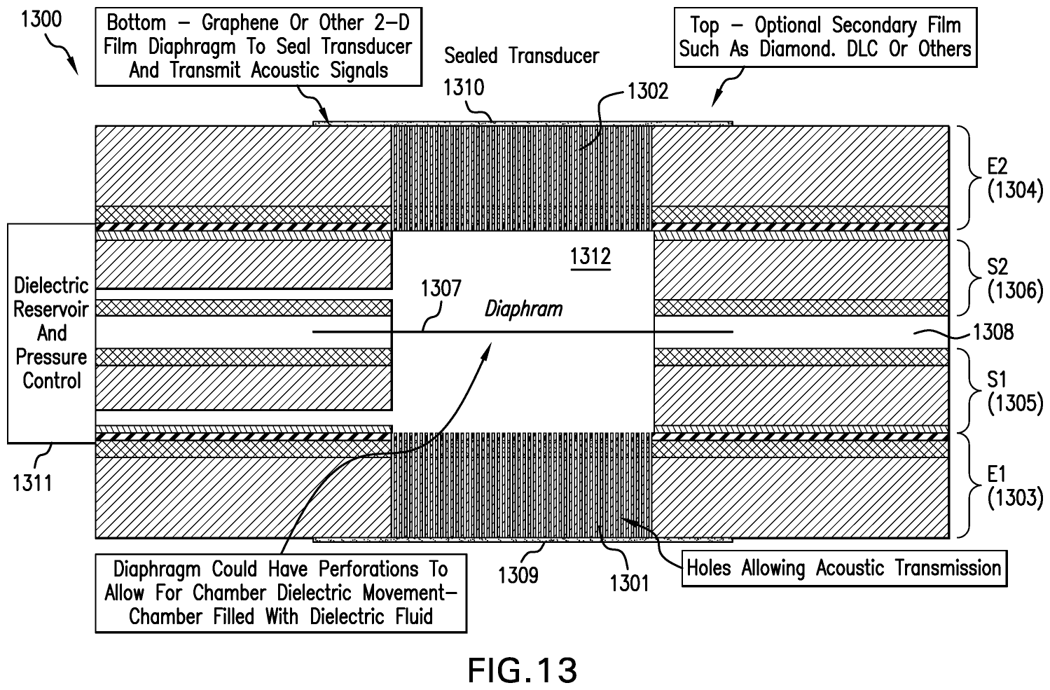

The embodiments shown in FIGS. 12 and 13 include options for a transducer with acoustic venting on both sides. FIG. 12 depicts an exemplary embodiment of a push/pull GMUTe device (1200) with exterior sealing for high pressure environments. As depicted, the device (1200) includes acoustic vent holes (1201), first electrode layer (1202), second electrode layer (1203), first spacer layer (1204), second spacer layer (1205), and diaphragm (1206). The acoustic vent holes (1201) permit acoustic transmission. On the outside of the first and/or second electrode layers (1202, 1203), and covering the vent holes (1201), there is a first sealing layer (1207) and/or a second sealing layer (1208). The first sealing layer (1207) may be made of graphene or another 2D film. The second sealing layer (1208) may be made of diamond, diamond-like carbon, or other similar materials. The first and/or second sealing layers (1207, 1208) seal the transducer against the environment/surroundings and transmit acoustic signals thereto. The first electrode layer (1202), second electrode layer (1203), first spacer layer (1204), second spacer layer (1205), and diaphragm (1206) have the same construction as described in FIG. 11, with layer (1209) shown in FIG. 12 corresponds with layer (1117) in FIG. 11.

Some embodiments include front acoustic holes, back acoustic holes, or both. Either combination of both front and back, or perhaps only forward or back-only acoustic holes may be desirable to tune the audio output. Optionally, an acoustic lid comprising graphene may be placed on or over the exterior of the vent holes to seal the transducer. This thin 2D layer of graphene would provide a very effective seal and would effectively coupling acoustic energy. It is expected that this sealing method could allow the device to operate to at high pressures, for example to significant depths, due to the mechanical strength of graphene.

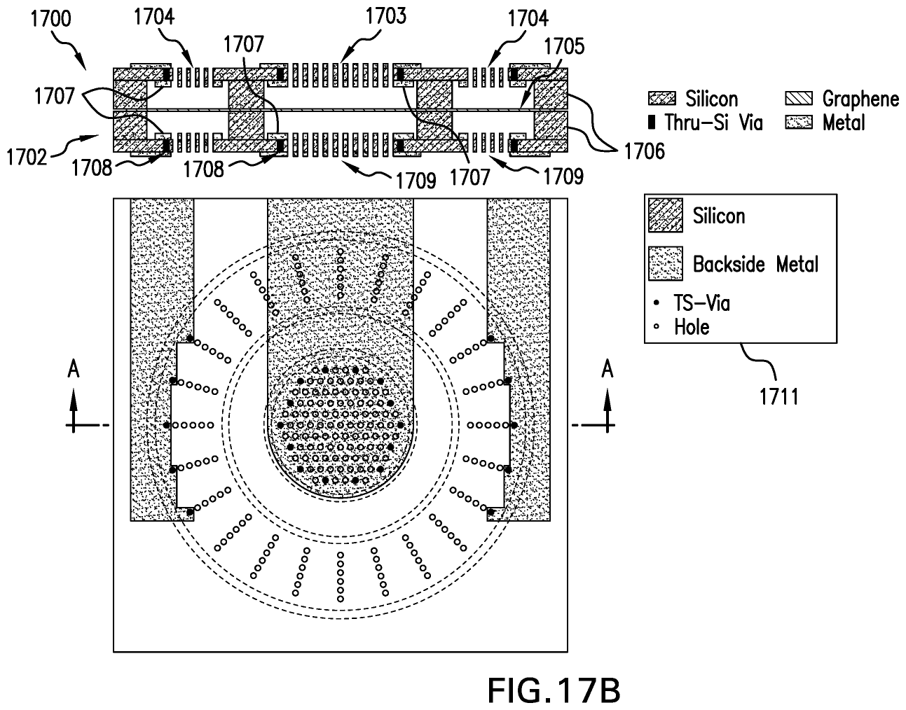

In some embodiments of the present application, the GMUT includes a coaxial transducer design. For example, FIG. 17 depicts one embodiment of a coaxial transducer design with a central circular graphene suspension surrounded by an outer ring transducer. This configuration can be used for echolocation and similar applications where the central transducer transmits an ultrasonic signal while the ring transducer receives reflected signals. FIG. 17 also shows a metallization approach for this exemplary embodiment, as well. The two cross-section drawings (section A-A) show a single-side transducer (at top of FIG. 17) and a push-pull configuration (bottom of FIG. 17), either of which can be implemented to realize the coaxial transducer pair.

FIGS. 17a and 17b depict an exemplary embodiment of a coaxial transducer architecture (1700). The top portions of FIGS. 17a and 17b are cross-sections of the bottom portions of FIGS. 17a and 17b through line A-A.

The top portion of FIG. 17a depicts a single side architecture (1701). The top portion of FIG. 17b depicts a push-pull architecture (1702). In both configurations (1701, 1702), the architecture (1700) is shown having a central circular graphene suspension (1703) surrounded by an outer ring transducer (1704). The configurations (1701, 1702) include a graphene diaphragm (1705) mounted on silicon (1706). A metal layer (1707) is provided on a portion of the silicon (1706) to act as an electrode, and through-silicon vias (TSVs) (1708) are provided for electrical connection to the metal layer (1707). Both configurations include acoustic vent holes (1709), which pass through the silicon (1706) and metal layers (1707).

The bottom portion of FIG. 17a depicts a top view of the configuration (1701), i.e. the single sided device. In this view, the center transducer (1703) is visible as a central circle, and the outer ring transducer (1704) is visible as a surrounding ring. With reference to the legend (1710), this view also shows the materials visible from the top perspective.

The bottom portion of FIG. 17b depicts a bottom view of configuration (1701) and a top/bottom view of configuration (1702). With reference to the legend (1711), this view shows the materials visible from the this perspective. In particular, the backside metal indicated provides electrical connection for the through-silicon vias (1708).

In some embodiments of the present application, other films can be added on top of the graphene or high strength 2D film to provide additional attributes as long as they are relatively thin. In some embodiments, diamond-like coatings, high-hardness materials such as Al₂O₃, and organic films such as PMMA, PEEK, or polyimides are provided increase mechanical strength, modifying stiffness, or protect internal components from electrical arcs. FIG. 13 shows an exemplary embodiment of such a configuration utilizing a pressure stabilization system (“dielectric reservoir and pressure control”) that may be desirable for the extreme pressures of deep-water sonar and echolocation, or other similar applications.

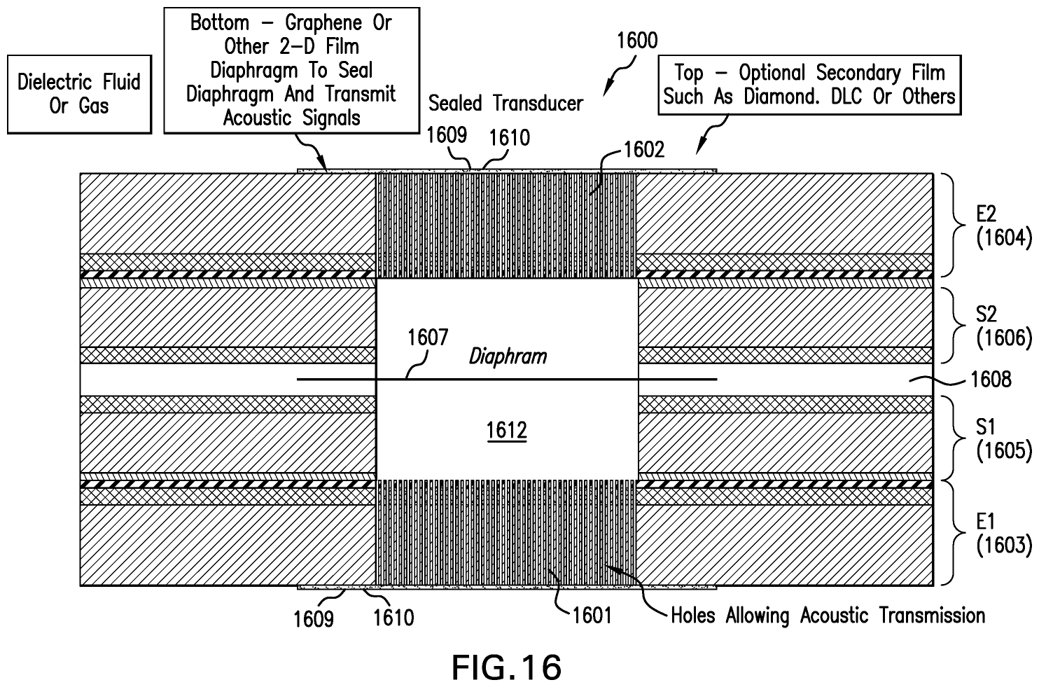

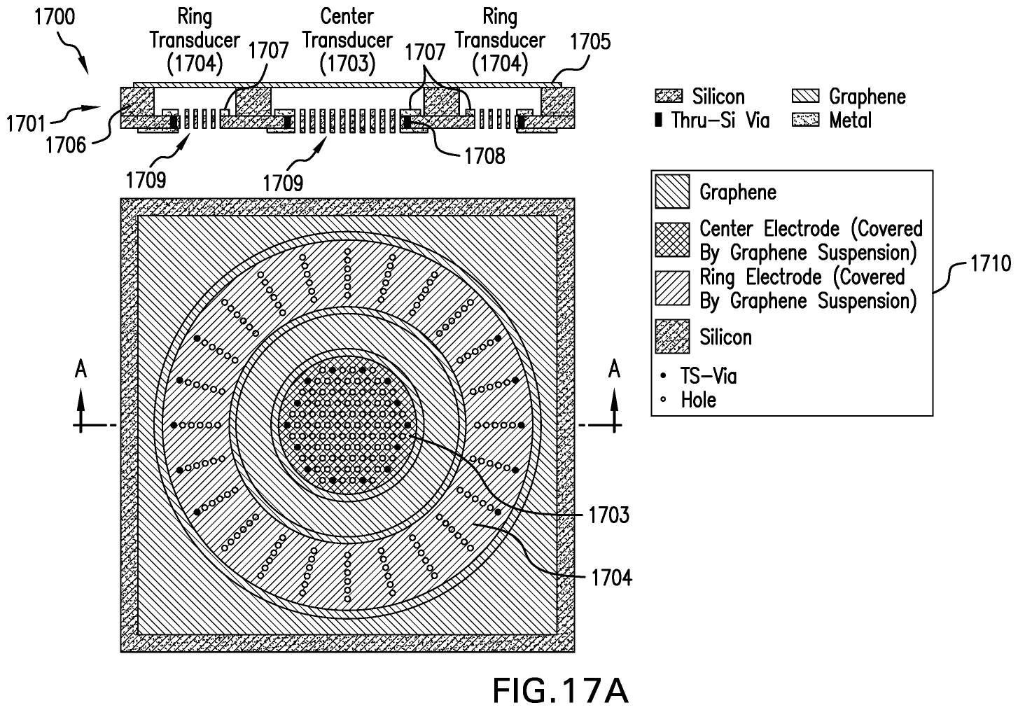

FIG. 13 depicts another exemplary embodiment of a push/pull GMUTe device (1300) with exterior sealing for high pressure environments. As depicted, the device (1300) includes acoustic vent holes (1301, 1302) on both sides of the device (1300) to permit acoustic transmission. The device further includes a first electrode layer (1303), second electrode layer (1304), first spacer layer (1305), second spacer layer (1306), and diaphragm (1307). On the outside of the first and second electrode layers (1303, 1304), and covering the vent holes (1301, 1302), there are first sealing layer (1309) and/or a second sealing layer (1310). The first sealing layer (1309) may be made of graphene or another 2D film. The second sealing layer (1310) may be made of diamond, diamond-like carbon, or other similar materials. The first and/or second sealing layers (1309, 1310) seal the transducer against the environment/surroundings and transmit acoustic signals thereto. The first electrode layer (1303), second electrode layer (1304), first spacer layer (1305), second spacer layer (1306), and diaphragm (1307) have the same construction as described in FIG. 11, with layer (1308) shown in FIG. 13 corresponds with layer (1117) in FIG. 11. The device (1300) also includes a dielectric reservoir and pressure control (1311) attached to a cavity (1312) in which the diaphragm (1307) resides. The cavity (1312) is thus filled with dielectric fluid. The diaphragm (1307) may include perforations (e.g. holes, slits, etc.) to permit dielectric fluid from the reservoir (1311) to move freely in the cavity (1312) from one side of the diaphragm (1307) to another. FIG. 16 depicts an exemplary embodiment of a transducer device (1600) sealed with dielectric fluid or gas. As depicted, the device (1600) includes acoustic vent holes (1601, 1602) on both sides of the device (1600) to permit acoustic transmission. The device further includes a first electrode layer (1603), second electrode layer (1604), first spacer layer (1605), second spacer layer (1606), and diaphragm (1607). On the outside of the first and second electrode layers (1603, 1604), and covering the vent holes (1601, 1602), there are first sealing layer (1609) and/or a second sealing layer (1610). The first sealing layer (1609) may be made of graphene or another 2D film. The second sealing layer (1610) may be made of diamond, diamond-like carbon, or other similar materials. The first and/or second sealing layers (1609, 1610) seal the transducer against the environment/surroundings and transmit acoustic signals thereto. The first electrode layer (1603), second electrode layer (1604), first spacer layer (1605), second spacer layer (1606), and diaphragm (1607) have the same construction as described in FIG. 11, with layer (1608) shown in FIG. 13 corresponds with layer (1117) in FIG. 11. The device (1600) also includes a cavity (1612) in which the diaphragm (1607) resides. The cavity (1612) is sealed by the first and/or second sealing layers (1609, 1601) and may contain a dielectric fluid. The diaphragm (1607) may include perforations (e.g. holes, slits, etc.) to permit dielectric fluid to move freely in the cavity (1612) from one side of the diaphragm (1607) to another.

In some embodiments the device comprises a rigid electrode on which a spacer is mounted. In some embodiments, rigid electrode is a sheet of aluminum that is anodized or non-conductive paint power coated on both sides to insulate the device from arching internally and isolate it externally. In some embodiments, the rigid electrode is either a glass, FR4, plastic or other insulating material, with a thin film conductive coating such as copper, aluminum, graphene or other such material. In some embodiments, the rigid electrode is either a glass, FR4, plastic or other insulating material, with a thin film conductive coating with an additional thin film insulating capping layer such as epoxy, SiO2, Silicon Nitride, Diamond or other such insulating material. In some embodiments, the rigid electrode has acoustic holes patterned.

In some embodiments, the rigid electrode has through holes patterned. In some embodiments, the holes are circular, squares, rectangles, kidney shaped or any other such desirable shape. In some embodiments, circular holes have a diameter of 100 microns to 20,000 microns, with other shaped geometries have similar transducing areas.

In another preferred embodiment, the diaphragm has a diameter of 1 pm to 10 pm. In another preferred embodiment, the diaphragm has a diameter of 10 pm to 100 pm. In another preferred embodiment, the diaphragm has a diameter of 100 pm to 1 mm. In another preferred embodiment, the diaphragm has a diameter of 40 pm to 1 mm. In another preferred embodiment, the diaphragm has a diameter of 1 mm to 10 mm. In another preferred embodiment, the diaphragm has a diameter of 1 mm to 35 mm. In another preferred embodiment, the diaphragm has a diameter of 1 mm to 100 mm. In another preferred embodiment, the diaphragm has a diameter of 10 mm to 20 mm. In another preferred embodiment, the diaphragm has a diameter of 10 mm to 100 mm. In another preferred embodiment, the diaphragm has a diameter of 100 mm to 1000 mm. In another preferred embodiment, the diaphragm has a diameter of 1000 mm to 10 cm. In another preferred embodiment, the diaphragm has a diameter of approximately 1 mm. In another preferred embodiment, the diaphragm has a diameter of approximately 10 mm. In another preferred embodiment, the diaphragm has a diameter of approximately 20 mm. In another preferred embodiment, the diaphragm has a diameter of approximately 30 mm. In another preferred embodiment, the diaphragm has a diameter of approximately 40 mm. In another preferred embodiment, the diaphragm has a diameter of approximately 50 mm. In another preferred embodiment, the diaphragm has a diameter of approximately 60 mm. In another preferred embodiment, the diaphragm has a diameter of approximately 70 mm. In another preferred embodiment, the diaphragm has a diameter of approximately 80 mm. In another preferred embodiment, the diaphragm has a diameter of approximately 90 mm. In another preferred embodiment, the diaphragm has a diameter of approximately 100 mm.

In another preferred embodiment, the diaphragm has a diameter of 50 μm to 100 μm. In another preferred embodiment, the diaphragm has a diameter of 50 μm to 200 μm. In another preferred embodiment, the diaphragm has a diameter of 50 μm to 300 μm. In another preferred embodiment, the diaphragm has a diameter of 50 μm to 400 μm. In another preferred embodiment, the diaphragm has a diameter of 50 μm to 500 μm. In another preferred embodiment, the diaphragm has a diameter of 100 μm to 200 μm. In another preferred embodiment, the diaphragm has a diameter of 100 μm to 300 μm. In another preferred embodiment, the diaphragm has a diameter of 100 μm to 400 μm. In another preferred embodiment, the diaphragm has a diameter of 100 μm to 500 μm. In another preferred embodiment, the diaphragm has a diameter of 200 μm to 300 μm. In another preferred embodiment, the diaphragm has a diameter of 200 μm to 400 μm. In another preferred embodiment, the diaphragm has a diameter of 200 μm to 500 μm. In another preferred embodiment, the diaphragm has a diameter of 300 μm to 400 μm. In another preferred embodiment, the diaphragm has a diameter of 300 μm to 500 μm. In another preferred embodiment, the diaphragm has a diameter of 400 μm to 500 μm.

In another preferred embodiment, the diaphragm has a diameter of approximately 50 μm. In another preferred embodiment, the diaphragm has a diameter of approximately 100 μm. In another preferred embodiment, the diaphragm has a diameter of approximately 200 μm. In another preferred embodiment, the diaphragm has a diameter of approximately 300 μm. In another preferred embodiment, the diaphragm has a diameter of approximately 400 μm. In another preferred embodiment, the diaphragm has a diameter of approximately 500 μm.

In some embodiments, devices of the present application are capable of emitting sound from 20 Hz to 10 GHz. In some embodiments, devices of the present application are capable of emitting sound from 20 kHz to 10 GHz. In some embodiments, devices of the present application are capable of emitting sound from 100 kHz to 10 GHz. In some embodiments, devices of the present application are capable of emitting sound from 1 MHz to 10 GHz. In some embodiments, devices of the present application are capable of emitting sound from 10 MHz to 10 GHz. In some embodiments, devices of the present application are capable of emitting sound from 100 MHz to 10 GHz. In some embodiments, devices of the present application are capable of emitting sound from 1 GHz to 10 GHz. In some embodiments, devices of the present application are capable of emitting sound from 20 Hz to 1 GHz. In some embodiments, devices of the present application are capable of emitting sound from 20 kHz to 1 GHz. In some embodiments, devices of the present application are capable of emitting sound from 100 kHz to 1 GHz. In some embodiments, devices of the present application are capable of emitting sound from 1 MHz to 1 GHz. In some embodiments, devices of the present application are capable of emitting sound from 10 MHz to 1 GHz. In some embodiments, devices of the present application are capable of emitting sound from 100 MHz to 1 GHz. In some embodiments, devices of the present application are capable of emitting sound from 20 Hz to 100 MHz. In some embodiments, devices of the present application are capable of emitting sound from 20 kHz to 100 MHz. In some embodiments, devices of the present application are capable of emitting sound from 100 kHz to 100 MHz. In some embodiments, devices of the present application are capable of emitting sound from 1 MHz to 100 MHz. In some embodiments, devices of the present application are capable of emitting sound from 10 MHz to 100 MHz. In some embodiments, devices of the present application are capable of emitting sound from 20 Hz to 10 MHz. In some embodiments, devices of the present application are capable of emitting sound from 20 kHz to 10 MHz. In some embodiments, devices of the present application are capable of emitting sound from 100 kHz to 10 MHz. In some embodiments, devices of the present application are capable of emitting sound from 1 MHz to 10 MHz. In some embodiments, devices of the present application are capable of emitting sound from 20 Hz to 1 MHz. In some embodiments, devices of the present application are capable of emitting sound from 20 kHz to 1 MHz. In some embodiments, devices of the present application are capable of emitting sound from 100 kHz to 1 MHz. In some embodiments, devices of the present application are capable of emitting sound from 20 Hz to 100 kHz. In some embodiments, devices of the present application are capable of emitting sound from 20 kHz to 100 kHz.

In some embodiments, the devices of the present application have a gap created by each spacer of 0.25 um to 300 um. In some embodiments, the devices of the present application have a gap of 2.5 um to 300 um. In some embodiments, the devices of the present application have a gap of 100 um to 300 um. In some embodiments, the devices of the present application have a gap of 200 um to 300 um. In some embodiments, the devices of the present application have a gap of 0.25 um to 200 um. In some embodiments, the devices of the present application have a gap of 2.5 um to 200 um. In some embodiments, the devices of the present application have a gap of 25 um to 200 um. In some embodiments, the devices of the present application have a gap of 100 um to 200 um. In some embodiments, the devices of the present application have a gap of 0.25 um to 100 um. In some embodiments, the devices of the present application have a gap of 2.5 um to 100 um. In some embodiments, the devices of the present application have a gap of 25 um to 100 um. In some embodiments, the devices of the present application have a gap of 0.25 um to 25 um. In some embodiments, the devices of the present application have a gap of 2.5 um to 25 um. In some embodiments, the devices of the present application have a gap of 0.25 um to 2.5 um.

In some embodiments, the hole size of the device is 0.125 um to 150 um. In some embodiments, the hole size of the device is 1.25 um to 150 um. In some embodiments, the hole size of the device is 12.5 um to 150 um. In some embodiments, the hole size of the device is 50 um to 150 um. In some embodiments, the hole size of the device is 100 um to 150 um. In some embodiments, the hole size of the device is 0.125 um to 100 um. In some embodiments, the hole size of the device is 1.25 um to 100 um. In some embodiments, the hole size of the device is 12.5 um to 100 um. In some embodiments, the hole size of the device is 50 um to 100 um. In some embodiments, the hole size of the device is 0.125 um to 50 um. In some embodiments, the hole size of the device is 1.25 um to 50 um. In some embodiments, the hole size of the device is 12.5 um to 50 um. In some embodiments, the hole size of the device is 0.125 um to 12.5 um. In some embodiments, the hole size of the device is 1.25 um to 12.5 um. In some embodiments, the hole size of the device is 0.125 um to 1.25 um.

In some embodiments, the bias voltage applied to the diaphragm is 0.25 V to 300 V. In some embodiments, the bias voltage applied to the diaphragm is 2.5 V to 300 V. In some embodiments, the bias voltage applied to the diaphragm is 25 V to 300 V. In some embodiments, the bias voltage applied to the diaphragm is 100 V to 300 V. In some embodiments, the bias voltage applied to the diaphragm is 200 V to 300 V. In some embodiments, the bias voltage applied to the diaphragm is 0.25 V to 200 V. In some embodiments, the bias voltage applied to the diaphragm is 2.5 V to 200 V. In some embodiments, the bias voltage applied to the diaphragm is 25 V to 200 V. In some embodiments, the bias voltage applied to the diaphragm is 100 to 200 V. In some embodiments, the bias voltage applied to the diaphragm is 0.25 V to 100 V. In some embodiments, the bias voltage applied to the diaphragm is 2.5 V to 100 V. In some embodiments, the bias voltage applied to the diaphragm is 25 V to 100 V. In some embodiments, the bias voltage applied to the diaphragm is 0.25 V to 25 V. In some embodiments, the bias voltage applied to the diaphragm is 2.5 V to 25 V. In some embodiments, the bias voltage applied to the diaphragm is 0.25 V to 2.5 V.

In some embodiments, the thickness of the diaphragm is 25 nm to 100 nm. In some embodiments, the thickness of the diaphragm is 100 nm to 200 nm. In some embodiments, the thickness of the diaphragm is 200 nm to 300 nm. In some embodiments, the thickness of the diaphragm is 300 nm to 400 nm. In some embodiments, the diaphragm comprises a single layer of graphene. In some embodiments, the diaphragm comprises 1-10 layers of graphene. In some embodiments, the diaphragm comprises 1-100 layers of graphene. In some embodiments, the diaphragm comprises 1-1000 layers of graphene. In some embodiments, the diaphragm comprises 10-100 layers of graphene. In some embodiments, the diaphragm comprises 100-1000 layers of graphene. In some embodiments, the diaphragm comprises 100-1000 layers of graphene. In some embodiments, the diaphragm comprises up to thousands of layers of graphene.

In some embodiments the interlayer interaction between layers of graphene will be modulated to improve cross-layer bonding. In some embodiments, there are dielectric layers on one or both sides of the graphene diaphragm.

### Self-Biasing/Electret

In another aspect, the present application provides a graphene electret transducer design, which the inventors of the present application will refer to as a GET (“graphene electret transducer”). In some embodiments, a GET would have a design similar to a graphene electrostatic transducer, including a GMUT or other design, while including electret materials. In some embodiments, the GET could have a second electrode to operate in push/pull mode in order to achieve higher efficiency and better sensitivity (diaphragm deflection/volt) much like a traditional electrostatic transducer. Most importantly, based on the physical properties of graphene, a GET configured either as a single- or dual-stator device has significant advantages over standard electrostatic transducers because of increased performance and lower power requirements.

Before discussing the specific details of certain embodiments of the GETs of the present application, the inventors note these embodiments may be modified to include aspects of the GMUTs discussed in this application.

Embodiments of the present application provide GET devices having an electret configuration. In particular, an electret is a stable material with a permanently embedded static electric dipole moment. In some embodiments, the material is a composite material.

In some embodiments of the present application, an electret configuration is employed to reduce the operating voltage required to drive the GET. The presence of a permanent dipole reduces the bias voltage required to generate mechanical force and drive the transducer in comparison to materials having no permanent dipole.

In some embodiments, an electret may be produced by injecting charge into a material associated with an electrode, e.g. the back plate of the transducer, or a material associated with the diaphragm. This charge will interact electrostatically with its opposing plate, transducing mechanical motion from electrical signal or electrical signal from mechanical motion in the transmit and receive modes respectively. Charge can be stored either on the surface of a dielectric or in the bulk volume of the material.

Thus, in some embodiments, a charge is injected into an electrically isolated conductor encapsulated by an insulator. The conductor/insulator combination may be layered on or applied to one or more electrodes or to the diaphragm of the transducer.

In other embodiments, the charge is injected into the top or bottom surface of a dielectric insulator layer applied on and/or covering an electrode. In some embodiments, the dielectric insulator is applied to the back-plate electrode, in others the dielectric is applied to the front electrode.

In another embodiment, the charge is injected into the bulk of a dielectric insulator layer applied on and/or covering an electrode. In some embodiments, the dielectric insulator is applied to the back-plate electrode, in others the dielectric is applied to the front electrode.

In another embodiment, the charge is injected into the surface or the bulk of a dielectric coating connected to the diaphragm. In some embodiments, the dielectric coating may cover one or both sides of the diaphragm, and one or both dielectrics may be charged.

In some embodiments, the dielectric material used in the foregoing embodiments is a polymer, e.g. a fluoropolymer. In some embodiments, the dielectric material is selected from the group consisting of PTFE (e.g. TEFLON), perfluorinated dioxole (e.g. TEFLON AF), cycloolefin copolymer, BCB, PFCB, FEP, PFA, PVDF, VDF, PE, PP, PET, PI, PMMA, EVA, Polyetherimide (PEI or “Ultem”) and copolymers thereof. In some embodiments, the dielectric material is a laminate comprising one or more of the foregoing polymer materials.

In some embodiments, the dielectric material used is an inorganic material. In some embodiments, the inorganic material is silicon dioxide (e.g. Quartz), silicon nitride, aluminum oxide, titanium dioxide, glass, PZT, a transition metal oxide, graphene oxide, fluorine-doped silicon oxide (e.g. F-TEOS), hafnium dioxide, hafnium silicate, zirconium dioxide, and combinations thereof. In some embodiments, the dielectric material is a multilayer structure comprising one or more of the foregoing inorganic materials. In some embodiments, the charge is applied to the foregoing dielectric materials using corona charging, thermal poling, contact charging, and/or electron beam irradiation.

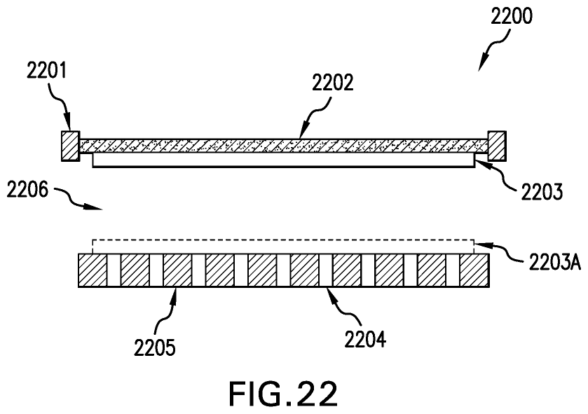

FIG. 22 depicts the cross-section of an exemplary embodiment of a single-sided electret device (2200) having a graphene transducer. This device may be configured as a microphone or a loudspeaker, however this configuration is preferred as a microphone. For this electret condenser microphone, the electret is attached to the graphene diaphragm like a front-facing ECM. For another embodiment of an open-faced ECM, the electret would be attached to the bottom electrode. To designate this alternative embodiment, the electret is outlined with dashed lines instead of a solid line.

Specifically, the device (2200) as depicted includes a conducting ring electrode (2201) electrically connected to graphene diaphragm (2202). An electret film (2203) is provided on one side of the diaphragm (2202). In FIG. 22, the film (2203) is shown on the back side of diaphragm (2202) (nearest to the electrode (2204)), however it is possible to configure the film (2203) on the other side of the diaphragm (2202). In an alternate embodiment, an electret film (2203A) is instead provided on the electrode (2204). The electret film may be of any form described in the present application. The device (2200) also includes a conducting electrode (2204) as referenced above. In the configuration shown, there are air gaps (2205) in the electrode (2204), but this is not strictly required for the device (2200) to operate. Between electrode (2204) and diaphragm (2202) with film (2203) there is a gap or cavity (2206).

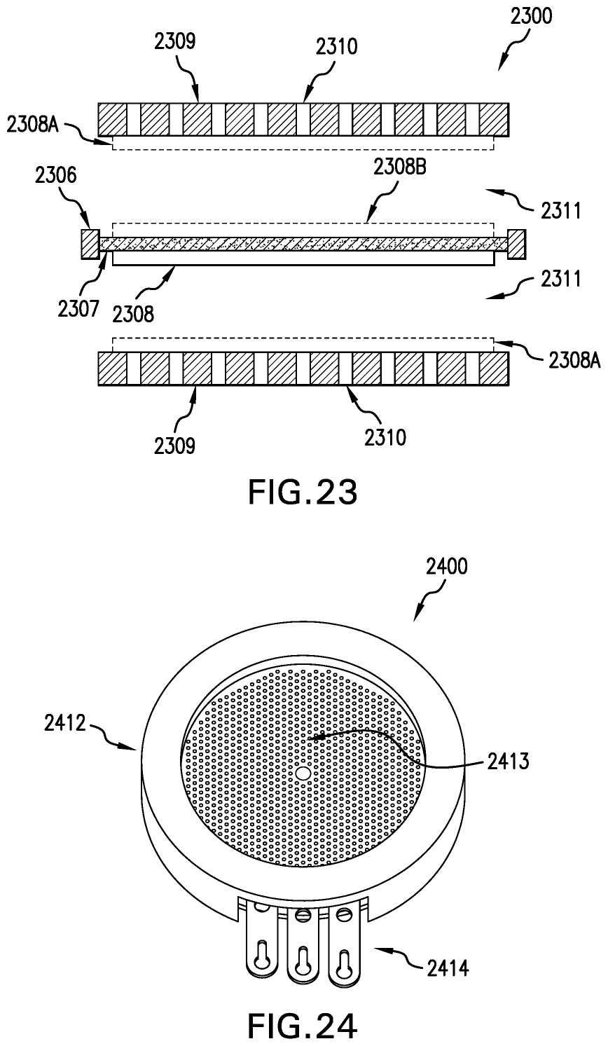

FIG. 23 depicts the cross-section of an exemplary embodiment of push-pull (two-sided) electret device (2300) having a graphene transducer. This device may be configured as a microphone or a loudspeaker, however this configuration is preferred as a loudspeaker. This transducer may function as a push-pull microphone or speaker, wherein two conducting electrodes are fixed parallel and equidistant from the diaphragm. In another embodiment, the electrets may be fixed to both top and bottom conducting electrode. To designate this alternative embodiment, the electrets are outlined with dashed lines instead of solid lines.

Specifically, the device (2300) as depicted includes a conducting ring electrode (2306) electrically connected to a graphene diaphragm (2307). The graphene diaphragm may have electret film (2308) and/or electret film (2308B) applied on one or both sides. In an alternate embodiment, an electret film (2308A) is applied to one or both electrodes (2309). The electret film may be of any form described in the present application. The device (2300) also includes two electrodes (2309). In the configuration shown, there are air gaps (2310) in the electrodes (2309), but this is not strictly required for the device (2300) to operate. Between the electrodes (2309) and the diaphragm (2307), there are gaps or cavities (2311).

FIG. 24 depicts a perspective view of a push-pull transducing device (2400) according to the present application. The device (2400) includes a perimeter clamp (2412) for applying a clamping force to the components of the transducer (2413) inside of the perimeter clamp (2412). The transducer (2413) is shown with a perforated electrode, i.e., an electrode with air gaps. The device (2400) includes electrode contacts (2414) extending from the perimeter claim (2412). Three contracts (2414) are shown, two of which are electrically connected to the electrodes, and one of which is electrically connected to the graphene diaphragm. The contacts (2414) permit electrical connection between the transducing device and the circuitry driving the device.

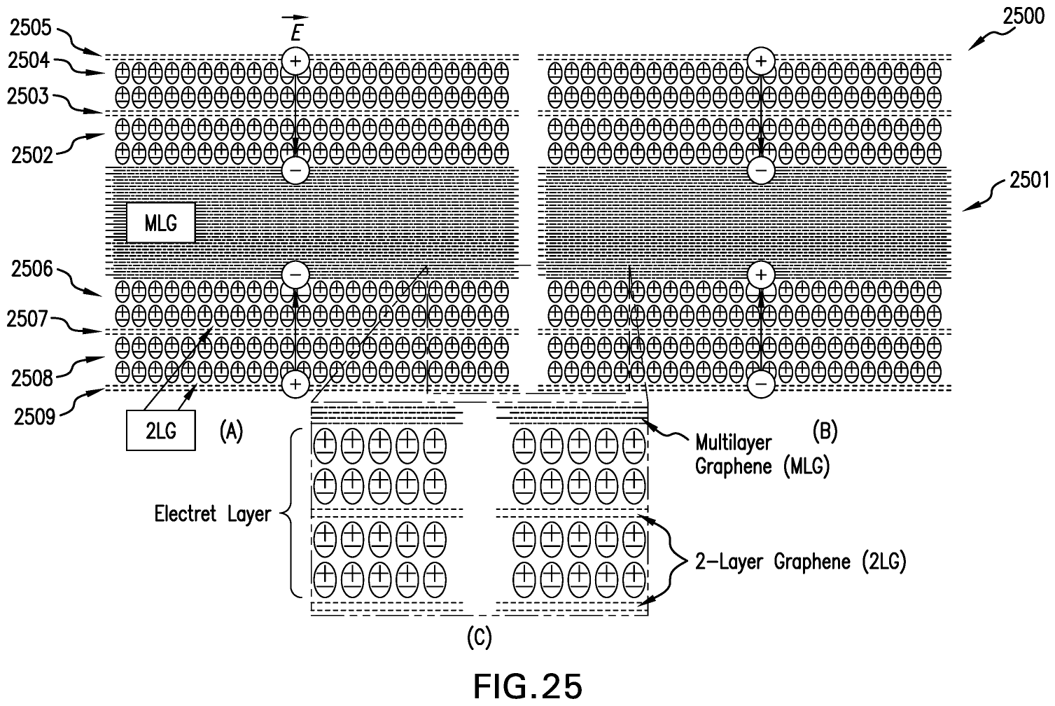

FIG. 25 depicts a cross-section of one embodiment of a graphene diaphragm (2500) having electret films applied to both surfaces of the diaphragm. The design of the diaphragm (2500) in this embodiment can permit higher charge density in the electret layers. This enables thinner, lower-mass electret layers, improving acoustic properties of the diaphragm (2500).

In particular, the diaphragm (2500) includes a multilayer graphene (MLG) core layer (2501). On top of the MLG core layer (2501), there is electret layer (2502), two-layer graphene (2LG) layer (2503), electret layer (2504), and 2LG layer (2505). In this embodiment, 2LG contains two atomic layers of graphene, whereas MLG contains up to thousands of atomic layers of graphene. Electret layer (2504) and 2LG layer (2505) are optional in this embodiment. Likewise, on the bottom of the MLG core layer (2501), there is electret layer (2506), 2LG layer (2507), electret layer (2508), and 2LG layer (2509). Electret layer (2508) and 2LG layer (2509) are optional in this embodiment.

The electret layers (2502, 2504, 2506, 2508) may comprise any of the materials discussed throughout this application that would be appropriate for such layers.

In other embodiments, the 2LG layers may each independently have 1, 2, 3, 4, 5, 6, 7, 8, 9, or 10 atomic layers of graphene. In other embodiments, the 2LG layers may each have 10-100 atomic layers of graphene. These atomically-thin layers, if built into the diaphragm structure as shown e.g. in FIG. 25, can be used as embedded electrodes to improve the electret charging process, resulting in a higher density of stored charge within the electret layers. This enables use of thinner, lower-mass electret layers. Because graphene is highly conductive and yet extremely thin, the use of 2LG layers enables enhanced charging capability while adding negligible mass to the diaphragm.

Panels A and B of FIG. 25 show two different dipole configurations for the diaphragm (2500). In Panel A, the dipoles of electret layers (2502, 2504, 2506, 2508) are all oriented such that the diaphragm (2500) has a net positive surface charge on both sides. In Panel B, the dipoles of electret layers (2502, 2504, 2506, 2508) are oriented such that the diaphragm (2500) has a net positive surface charge on its top side and a net negative surface charge on its bottom side. The inset in Panel C shows both configurations in greater detail.

A multilayer graphene layer (e.g. the MLG layer in FIG. 25) provides low mass and high mechanical strength, while the electret layers provide a permanent charge and increase overall diaphragm strength. The fraction of MLG to electret materials can vary from 90% MLG to 10% MLG, depending on the desired structure, the application and charge storage requirements.

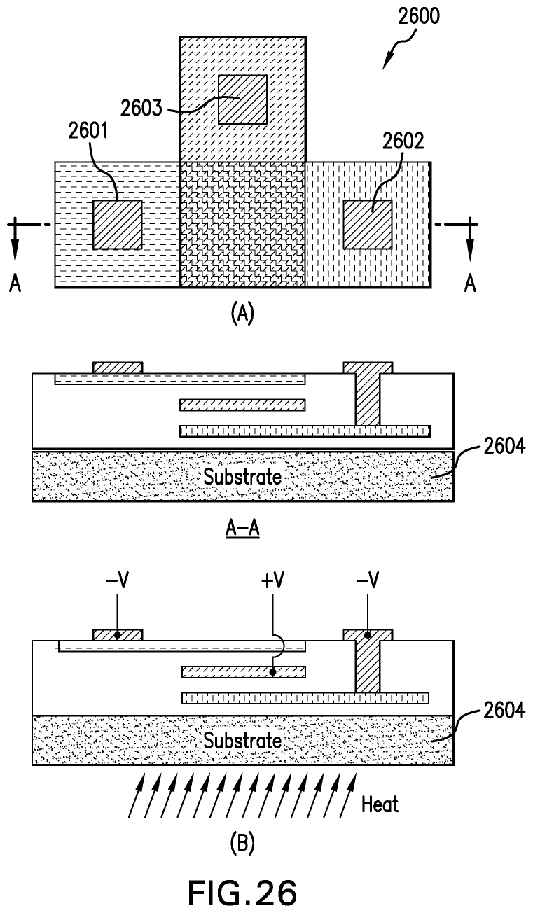

FIG. 26 depicts one way of applying a quasi-permanent electric charge to the embodiment according to FIG. 25. In particular, Panel A shows a top down view of the device (2600), in which the electrodes are extended to accommodate electrode pads (2601, 2602, 2603). In other words, electrode pads (2601, 2602, 2603) are individually electrically connected to the MLG core layer and at least two of the 2LG layers in the device (2600). The 2LG layers thus function as embedded electrodes to aid the electret charging process. Cross-section A-A shows the device (2600) laying on a substrate (2604). Panel B shows a voltage (−V) applied to electrode pads (2601, 2603) and a voltage (+V) applied to electrode pad (2602) while heat is applied to substrate (2604). In this way, a quasi-permanent electric charge may be applied to the electret layers in device (2600).

In push-pull configuration, the two electret dielectric layers can be applied to the diaphragm either before or after charging the electret layers. If applied prior to charging, the multi-layer graphene (MLG) layer can be used as a common electrode during the charging process so that the two electret layers between electrode layers are charged simultaneously. Application of heat to the test structure is used to raise the temperature to greater that the dielectric Curie temperature during the charging process. To implement other charge configurations, the dielectric material between each pair of electrode layers shown in Figure Y can be charged separately by contacting only two adjacent electrode layers at a time. In any case, after electret charging, the probe pads can be covered with dielectric so that the entire electret structure is encased by dielectric materials to eliminate charge leakage paths.

In an alternate embodiment, the charge may be applied on the top side and bottom sides of the diaphragm separately, by only applying a potential across two of the electrodes at a time. Alternatively, the electret layers may be charged prior to application on the diaphragm. In any event, the electrode pads (2601, 2602, and 2603) can be covered with a dielectric material after charging to encase the electret structure in dielectric materials to eliminate charge leakage paths.

In some embodiments, in the diaphragm it may be desirable to use a composite graphene structure that includes thin layers of HBN, MoS2 or more conventional materials on one or both sides of the graphene layer to provide additional mechanical strength to the diaphragm, to provide a more-flexible, less-rigid mechanical support along the outer perimeter of the diaphragm, or to create a desired displacement pattern across the diaphragm surface to essentially ‘tune’ or ‘enhance’ the diaphragm's excursion profile in response to applied electrostatic forces. Such patterns would include, for example in a round diaphragm, patterning a disc at the center or a ring with a certain width and radius into the circular diaphragm. Conventional materials that could be used include but are not limited to polymers such as PEEK (Polyether ether ketone), FEP (Fluorinated ethylene propylene) or a wide range of acrylics, polyesters, silicones, polyurethanes, and halogenated plastics. The patterned disc would increase the mass of the diaphragm and reduce its displacement compared to a diaphragm without the patterned disc. Another pattern, the ring for example at the outer edge of the diaphragm would add rigidity to the diaphragm and also reduce its displacement but would enhance its durability. For example, the diaphragm with a patterned ring along its outer perimeter would be able to be driven at higher voltages compared with a diaphragm without a patterned ring.

The embodiments described herein would generally be able to both transmit and receive in a single device from a front side of the device. In such a configuration, an electrode in the device could be mounted to a dampening system or the electrode itself could be a dampener (i.e. made of dampening material) that has been coated to achieve sufficient electrical properties to also act as an electrode. A person of ordinary skill in the art would understand there are many possible configurations of such an electrode/damping system.

The embodiments described herein would also generally be able to both transmit and receive in a single device from both the front and back of the device. In such a configuration, the device could optionally utilize separate microphone transducers (dampened rear electrodes) to discriminate the direction of the incoming signal.

In some embodiments the device comprises a rigid electrode on which a spacer is mounted. In some embodiments, rigid electrode is a sheet of aluminum that is anodized or non-conductive paint power coated on both sides to insulate the device from arching internally and isolate it externally. In some embodiments, the rigid electrode is either a glass, FR4, plastic or other insulating material, with a thin film conductive coating such as copper, aluminum, graphene or other such material. In some embodiments, the rigid electrode is either a glass, FR4, plastic or other insulating material, with a thin film conductive coating with an additional thin film insulating capping layer such as epoxy, SiO2, Silicon Nitride, Diamond or other such insulating material. In some embodiments, the rigid electrode has acoustic holes patterned.

In some embodiments, the rigid electrode has through holes patterned. In some embodiments, the holes are circular, squares, rectangles, kidney shaped or any other such desirable shape. In some embodiments, circular holes have a diameter of 100 microns to 20,000 microns, with other shaped geometries have similar transducing areas.

In another preferred embodiment, the diaphragm has a diameter of 1 μm to 10 μm. In another preferred embodiment, the diaphragm has a diameter of 10 μm to 100 μm. In another preferred embodiment, the diaphragm has a diameter of 100 μm to 1 mm. In another preferred embodiment, the diaphragm has a diameter of 40 μm to 1 mm. In another preferred embodiment, the diaphragm has a diameter of 1 mm to 10 mm. In another preferred embodiment, the diaphragm has a diameter of 1 mm to 35 mm. In another preferred embodiment, the diaphragm has a diameter of 1 mm to 100 mm. In another preferred embodiment, the diaphragm has a diameter of 10 mm to 20 mm. In another preferred embodiment, the diaphragm has a diameter of 10 mm to 100 mm. In another preferred embodiment, the diaphragm has a diameter of 100 mm to 1000 mm. In another preferred embodiment, the diaphragm has a diameter of 1000 mm to 10 cm. In another preferred embodiment, the diaphragm has a diameter of approximately 1 mm. In another preferred embodiment, the diaphragm has a diameter of approximately 10 mm. In another preferred embodiment, the diaphragm has a diameter of approximately 20 mm. In another preferred embodiment, the diaphragm has a diameter of approximately 30 mm. In another preferred embodiment, the diaphragm has a diameter of approximately 40 mm. In another preferred embodiment, the diaphragm has a diameter of approximately 50 mm. In another preferred embodiment, the diaphragm has a diameter of approximately 60 mm. In another preferred embodiment, the diaphragm has a diameter of approximately 70 mm. In another preferred embodiment, the diaphragm has a diameter of approximately 80 mm. In another preferred embodiment, the diaphragm has a diameter of approximately 90 mm. In another preferred embodiment, the diaphragm has a diameter of approximately 100 mm.

In another preferred embodiment, the diaphragm has a diameter of 50 μm to 100 μm. In another preferred embodiment, the diaphragm has a diameter of 50 μm to 200 μm. In another preferred embodiment, the diaphragm has a diameter of 50 μm to 300 μm. In another preferred embodiment, the diaphragm has a diameter of 50 μm to 400 μm. In another preferred embodiment, the diaphragm has a diameter of 50 μm to 500 μm. In another preferred embodiment, the diaphragm has a diameter of 100 μm to 200 μm. In another preferred embodiment, the diaphragm has a diameter of 100 μm to 300 μm. In another preferred embodiment, the diaphragm has a diameter of 100 μm to 400 μm. In another preferred embodiment, the diaphragm has a diameter of 100 μm to 500 μm. In another preferred embodiment, the diaphragm has a diameter of 200 μm to 300 μm. In another preferred embodiment, the diaphragm has a diameter of 200 μm to 400 μm. In another preferred embodiment, the diaphragm has a diameter of 200 μm to 500 μm. In another preferred embodiment, the diaphragm has a diameter of 300 μm to 400 μm. In another preferred embodiment, the diaphragm has a diameter of 300 μm to 500 μm. In another preferred embodiment, the diaphragm has a diameter of 400 μm to 500 μm.

In another preferred embodiment, the diaphragm has a diameter of approximately 50 μm. In another preferred embodiment, the diaphragm has a diameter of approximately 100 μm. In another preferred embodiment, the diaphragm has a diameter of approximately 200 μm. In another preferred embodiment, the diaphragm has a diameter of approximately 300 μm. In another preferred embodiment, the diaphragm has a diameter of approximately 400 μm. In another preferred embodiment, the diaphragm has a diameter of approximately 500 μm.

In some embodiments, devices of the present application are capable of emitting sound from 20 Hz to 10 GHz. In some embodiments, devices of the present application are capable of emitting sound from 20 kHz to 10 GHz. In some embodiments, devices of the present application are capable of emitting sound from 100 kHz to 10 GHz. In some embodiments, devices of the present application are capable of emitting sound from 1 MHz to 10 GHz. In some embodiments, devices of the present application are capable of emitting sound from 10 MHz to 10 GHz. In some embodiments, devices of the present application are capable of emitting sound from 100 MHz to 10 GHz. In some embodiments, devices of the present application are capable of emitting sound from 1 GHz to 10 GHz. In some embodiments, devices of the present application are capable of emitting sound from 20 Hz to 1 GHz. In some embodiments, devices of the present application are capable of emitting sound from 20 kHz to 1 GHz. In some embodiments, devices of the present application are capable of emitting sound from 100 kHz to 1 GHz. In some embodiments, devices of the present application are capable of emitting sound from 1 MHz to 1 GHz. In some embodiments, devices of the present application are capable of emitting sound from 10 MHz to 1 GHz. In some embodiments, devices of the present application are capable of emitting sound from 100 MHz to 1 GHz. In some embodiments, devices of the present application are capable of emitting sound from 20 Hz to 100 MHz. In some embodiments, devices of the present application are capable of emitting sound from 20 kHz to 100 MHz. In some embodiments, devices of the present application are capable of emitting sound from 100 kHz to 100 MHz. In some embodiments, devices of the present application are capable of emitting sound from 1 MHz to 100 MHz. In some embodiments, devices of the present application are capable of emitting sound from 10 MHz to 100 MHz. In some embodiments, devices of the present application are capable of emitting sound from 20 Hz to 10 MHz. In some embodiments, devices of the present application are capable of emitting sound from 20 kHz to 10 MHz. In some embodiments, devices of the present application are capable of emitting sound from 100 kHz to 10 MHz. In some embodiments, devices of the present application are capable of emitting sound from 1 MHz to 10 MHz. In some embodiments, devices of the present application are capable of emitting sound from 20 Hz to 1 MHz. In some embodiments, devices of the present application are capable of emitting sound from 20 kHz to 1 MHz. In some embodiments, devices of the present application are capable of emitting sound from 100 kHz to 1 MHz. In some embodiments, devices of the present application are capable of emitting sound from 20 Hz to 100 kHz. In some embodiments, devices of the present application are capable of emitting sound from 20 kHz to 100 kHz.

In some embodiments, the devices of the present application have a gap created by each spacer of 0.25 um to 300 um. In some embodiments, the devices of the present application have a gap of 2.5 um to 300 um. In some embodiments, the devices of the present application have a gap of 100 um to 300 um. In some embodiments, the devices of the present application have a gap of 200 um to 300 um. In some embodiments, the devices of the present application have a gap of 0.25 um to 200 um. In some embodiments, the devices of the present application have a gap of 2.5 um to 200 um. In some embodiments, the devices of the present application have a gap of 25 um to 200 um. In some embodiments, the devices of the present application have a gap of 100 um to 200 um. In some embodiments, the devices of the present application have a gap of 0.25 um to 100 um. In some embodiments, the devices of the present application have a gap of 2.5 um to 100 um. In some embodiments, the devices of the present application have a gap of 25 um to 100 um. In some embodiments, the devices of the present application have a gap of 0.25 um to 25 um. In some embodiments, the devices of the present application have a gap of 2.5 um to 25 um. In some embodiments, the devices of the present application have a gap of 0.25 um to 2.5 um.

In some embodiments, the hole size of the device is 0.125 um to 150 um. In some embodiments, the hole size of the device is 1.25 um to 150 um. In some embodiments, the hole size of the device is 12.5 um to 150 um. In some embodiments, the hole size of the device is 50 um to 150 um. In some embodiments, the hole size of the device is 100 um to 150 um. In some embodiments, the hole size of the device is 0.125 um to 100 um. In some embodiments, the hole size of the device is 1.25 um to 100 um. In some embodiments, the hole size of the device is 12.5 um to 100 um. In some embodiments, the hole size of the device is 50 um to 100 um. In some embodiments, the hole size of the device is 0.125 um to 50 um. In some embodiments, the hole size of the device is 1.25 um to 50 um. In some embodiments, the hole size of the device is 12.5 um to 50 um. In some embodiments, the hole size of the device is 0.125 um to 12.5 um. In some embodiments, the hole size of the device is 1.25 um to 12.5 um. In some embodiments, the hole size of the device is 0.125 um to 1.25 um.

In some embodiments, the bias voltage applied to the diaphragm is 0.25 V to 300 V. In some embodiments, the bias voltage applied to the diaphragm is 2.5 V to 300 V. In some embodiments, the bias voltage applied to the diaphragm is 25 V to 300 V. In some embodiments, the bias voltage applied to the diaphragm is 100 V to 300 V. In some embodiments, the bias voltage applied to the diaphragm is 200 V to 300 V. In some embodiments, the bias voltage applied to the diaphragm is 0.25 V to 200 V. In some embodiments, the bias voltage applied to the diaphragm is 2.5 V to 200 V. In some embodiments, the bias voltage applied to the diaphragm is 25 V to 200 V. In some embodiments, the bias voltage applied to the diaphragm is 100 to 200 V. In some embodiments, the bias voltage applied to the diaphragm is 0.25 V to 100 V. In some embodiments, the bias voltage applied to the diaphragm is 2.5 V to 100 V. In some embodiments, the bias voltage applied to the diaphragm is 25 V to 100 V. In some embodiments, the bias voltage applied to the diaphragm is 0.25 V to 25 V. In some embodiments, the bias voltage applied to the diaphragm is 2.5 V to 25 V. In some embodiments, the bias voltage applied to the diaphragm is 0.25 V to 2.5 V.

In some embodiments, the thickness of the diaphragm is 25 nm to 100 nm. In some embodiments, the thickness of the diaphragm is 100 nm to 200 nm. In some embodiments, the thickness of the diaphragm is 200 nm to 300 nm. In some embodiments, the thickness of the diaphragm is 300 nm to 400 nm. In some embodiments, the diaphragm comprises a single layer of graphene. In some embodiments, the diaphragm comprises 1-10 layers of graphene. In some embodiments, the diaphragm comprises 1-100 layers of graphene. In some embodiments, the diaphragm comprises 1-1000 layers of graphene. In some embodiments, the diaphragm comprises 10-100 layers of graphene. In some embodiments, the diaphragm comprises 100-1000 layers of graphene. In some embodiments, the diaphragm comprises 100-1000 layers of graphene. In some embodiments, the diaphragm comprises up to thousands of layers of graphene.

In some embodiments the interlayer interaction between layers of graphene will be modulated to improve cross-layer bonding. In some embodiments, there are dielectric layers on one or both sides of the graphene diaphragm.

### Electronics and Operation

Certain embodiments of the present application include a GET having transmit and receive circuit configurations as discussed herein. In some embodiments, to transmit a signal, the transducer is connected to a voltage amplifier (and/or a step-up transformer circuit) to amplify the ultrasonic signal and split the signal into positive and negative components to achieve the output power. To receive signals, the transducer can be connected to a either a voltage-sense circuit or a current-sense, transimpedance amplifier to monitor the change in charge on the diaphragm as a result of the change in spacing between diaphragm and electrode. Capacitor-based electrostatic receivers operate at higher frequencies when using a current-sensing transimpedance amplifier and can achieve a more consistent gain at higher frequencies as compared to voltage-sensing circuits, primarily due to the fundamental operating principles of capacitors where current through a capacitor can flow instantaneously but the voltage across a capacitor cannot change instantaneously.

Certain embodiments of the present application include a GMUT having transmit and receive circuit configurations as discussed herein. In some embodiments, to transmit a signal, the transducer is connected to a voltage amplifier (and/or a step-up transformer circuit) to amplify the ultrasonic signal and split the signal into positive and negative components to achieve the output power. To receive signals, the transducer can be connected to a either a voltage-sense circuit or a current-sense, transimpedance amplifier to monitor the change in charge on the diaphragm as a result of the change in spacing between diaphragm and electrode. Capacitor-based electrostatic receivers operate at higher frequencies when using a current-sensing transimpedance amplifier and can achieve a more consistent gain at higher frequencies as compared to voltage-sensing circuits, primarily due to the fundamental operating principles of capacitors where current through a capacitor can flow instantaneously but the voltage across a capacitor cannot change instantaneously.

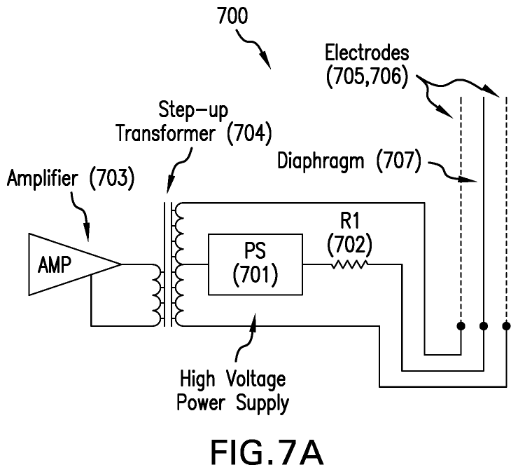

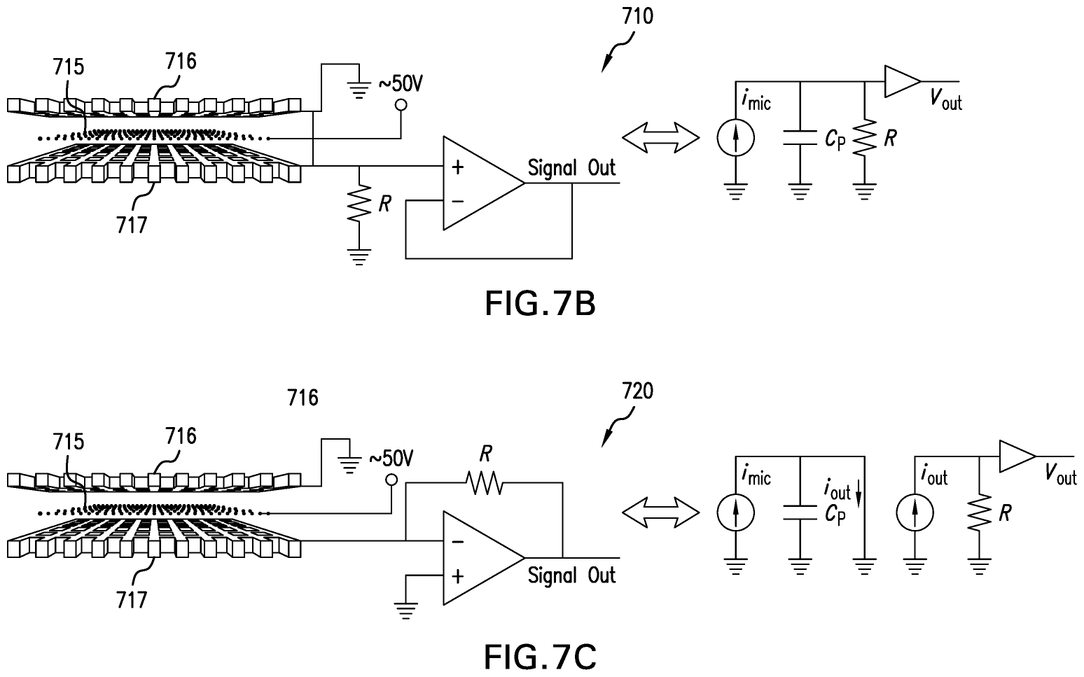

FIG. 7 depicts circuitry for an exemplary GMUT device. Specifically, FIG. 7 depicts circuitry which may be used to operate embodiments of the present application. FIG. 7a depicts a GMUT transmission circuit (700), in which PS is a high voltage power supply (701), R1 is a resistor (702), and AMP is an amplifier (703). The circuit (700) also includes a step-up transformer (704). As shown, the circuit (700) is electrically connected to electrodes (705, 706) and diaphragm (707). FIGS. 7b and 7c depict two GMUT receiver circuit configurations. FIG. 7b depicts a GMUT receiver circuit (710). The circuit (710) uses a voltage sense amplifier that becomes bandwidth-limited by RCp time constant. FIG. 7c depicts a GMUT receiver circuit (720). The circuit (720) uses a high-speed, low-noise, current-sense transimpedance amplifier with high-frequency detection capability. In FIGS. 7b and 7c, the diaphragm (715) is shown as connected to a 50V power supply, and the electrodes (716, 717) are shown connected to the circuits (710) and (720).

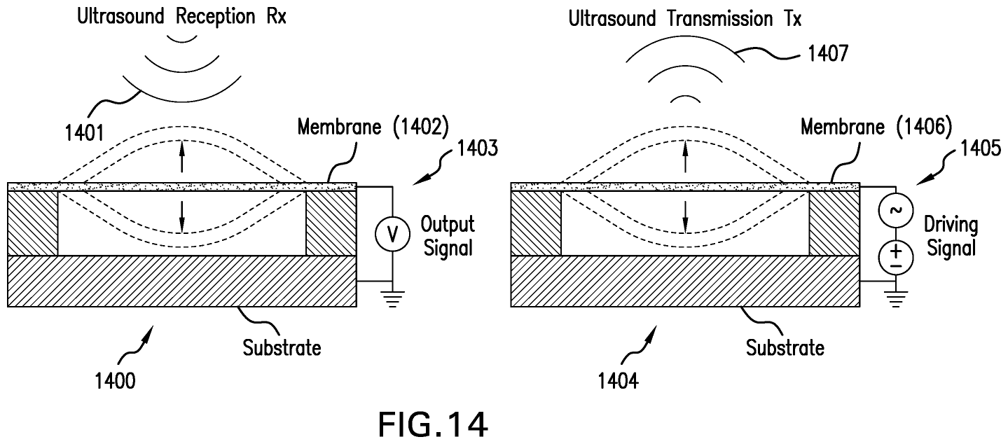

FIG. 14 depicts an exemplary embodiment of transmitter and receiver electronics configuration for an open face transducer, in particular simplified circuitry which may be used to operate embodiments of the present application in transmission and receiving modes. In the device (1400) on the left, ultrasound (1401) vibrates the membrane (1402), generating an electrical output signal in circuitry (1403) which can be measured to characterize the ultrasound (1401). In device (1404) on the right, a driving signal is generated in circuitry (1405), which vibrates the membrane (1406) to produce ultrasound (1407). Both devices (1400, 1401) may be constructed as any of the embodiments of the present application.

In another embodiment, the dimensions of the GMUT are such that the transducer can receive signals in the sonic range, for example between 20 Hz and 20 kHz. Such a transducer may be configured as a MEMS microphone. In several embodiments, the MEMS microphone can include the same sizes and shapes described in other GMUT embodiments set forth in this application. A MEMS microphone embodiment will necessarily operate in receive mode and will be biased at levels described in other GMUT embodiments set forth in this application. In a particularly preferred embodiment, a MEMS microphone will have holes for sound to pass through at sizes described in other GMUT embodiments set forth in this application.

In another embodiment of the present application, the GMUT is configured in a collapse mode or collapse-snapback mode. In these two configurations, the voltage applied by the electric field generated at the electrode or electrodes on the graphene diaphragm is greater than the “pull-in” voltage. As a result, a central region of graphene diaphragm comes into semi-permanent physical contact with an insulating material deposited above the electrode. In particular, so long as the electric field is greater than the pull in voltage, at least a central portion of the graphene will remain in physical contact with the insulating material. The insulating material is preferably present to prevent a short circuit between the diaphragm and the electrode. In some embodiments, the insulating layer may instead be arranged on the graphene diaphragm in the form of a polymeric or ALD deposited insulator or the like. Where the graphene diaphragm has an insulating later, there would be no need for an insulating layer on the electrode, meaning the diaphragm could come into direct contact with the electrode.

In a collapse mode configuration, holes may be provided in the electrode and the optional insulating material. Such holes are covered by the central region of the graphene diaphragm while it is in semi-permanent physical contact with the insulating material. Although the central region maintains contact with the insulating material, the portions of the graphene diaphragm covering the holes are effectively suspended. These effectively-suspended portions of the graphene are free to vibrate to produce sound in response to an electric field generated at the electrode. In collapse mode, the electric field may be operated in such a way as to actuate the portion of the graphene diaphragm covering the holes while still maintaining the “pull-in” voltage.

In another collapse mode embodiment, a peripheral region between the central region and the edge of the diaphragm is suspended. In such an embodiment, the device is operated while keeping the center of the diaphragm touching the insulating material and only actuating the peripheral region that is still free. In this way, the peripheral regions are able to produce a response. In some embodiments, either or both the peripheral regions and holes covered by the graphene diaphragm are actuated to produce a response.

In a collapse-snapback mode, the device is operated in a manner involving the diaphragm touching the insulating material and then releasing. In certain embodiments of the collapse-snapback mode, the pressure output of the transducer nearly doubles as compared to a normal operating mode in which the device does not touch the insulating material. This method of actuation is especially attractive for use with graphene due to its higher mechanical strength than traditional metalized silicon nitride or doped poly-silicon CMUTs used today.

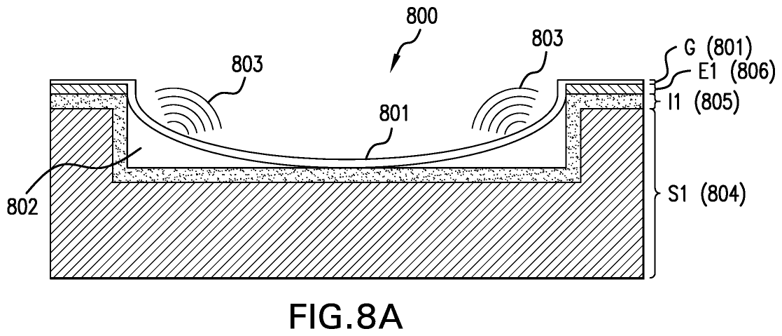

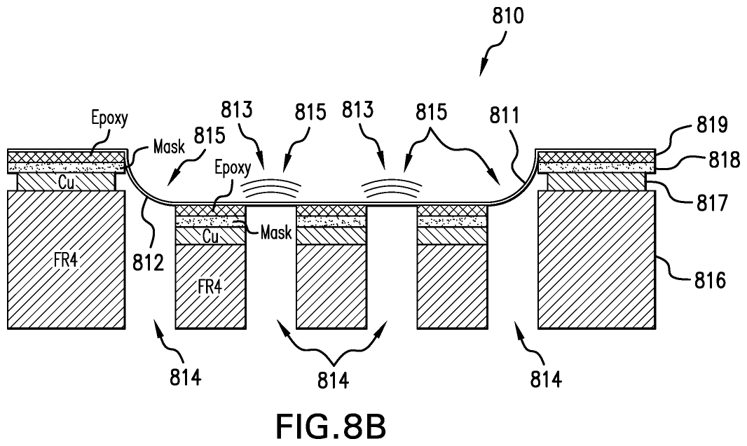

An example of a collapse mode configuration or a collapse-snapback mode configuration is shown in FIG. 8, in which the suspended portion is indicated with lines showing emission of sound. FIG. 8a shows the diaphragm (801) collapsed into a continuous cavity (802), whereas FIG. 8b shows the diaphragm (811) collapsed into a cavity (812) having holes (813). In FIG. 8b, the diaphragm is capable of emitting sound from the portions (814) overlaying each hole, providing additional opportunities for tuning the response if desired. Both configurations shown in FIGS. 8a and 8b can be used for operation in collapse mode or collapse-snapback mode. In FIGS. 8a and 8b, the suspended portion is indicated with lines (803, 813)) showing emission of sound. The devices (800, 810) shown in FIGS. 8a and 8b may be constructed according to any of the GMUT embodiments disclosed in this application. The device (800) in FIG. 8a as depicted includes a substrate layer (804), an electrode and/or dielectric layer (805), and a bonding layer (806). In the case layer (805) is a dielectric, an electrode would be provided elsewhere. The deice (810) in FIG. 8b as depicted includes a substrate (816) (which is shown made from FR4), an electrode layer (817) (shown as made from Copper), a mask layer (818), and an epoxy layer (819).

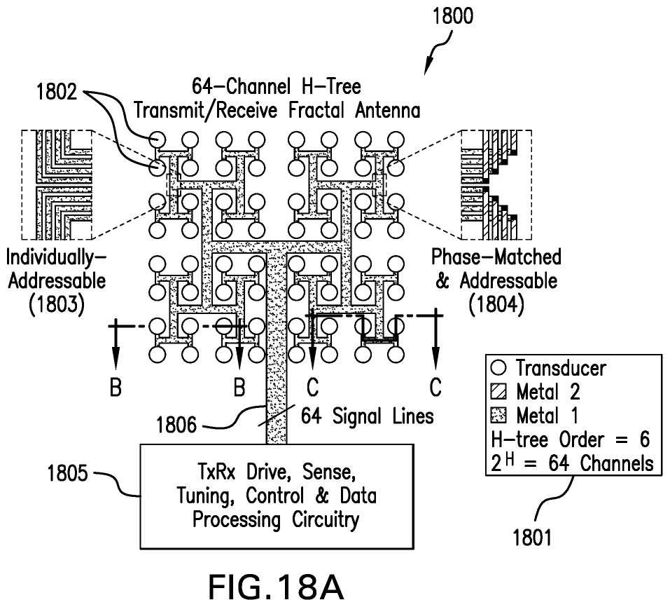

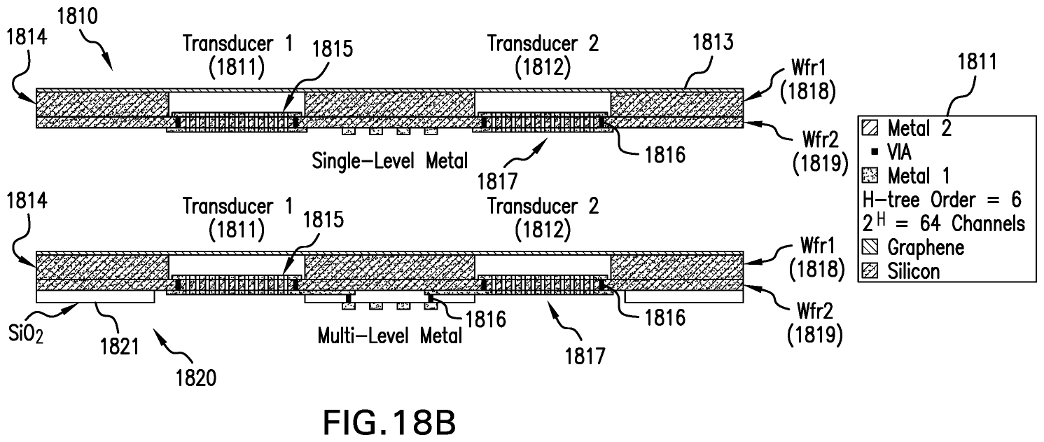

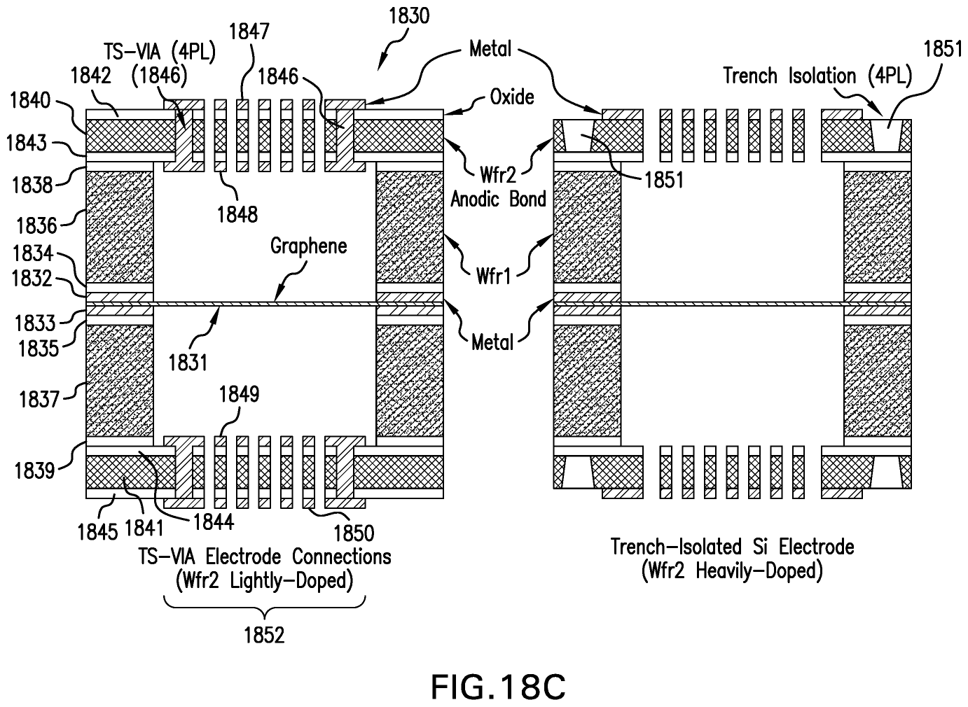

In another embodiment of the present application, devices as discussed herein may be arranged in an antenna design for transmit/receive TxRx and beamforming applications. One exemplary embodiment of such an application is shown in FIG. 18, depicting a 64-channel H-Tree fractal antenna design. As shown, a single metal layer may be used to individually address each of the 64 transducers in the array. As shown, in an alternative configuration, a second metal layer can be added to achieve an array where all 64 elements are phase-matched. The phase-matching arises because all interconnects between the processing circuitry and the individual transducers have the same wire length. Phase-matching allows high-precision beamforming to be accomplished, for example by using the so-called “total focusing method.”

FIGS. 18a and 18b depict an exemplary embodiment of a phase-matched fractal antenna architecture (1800). With reference to the legend (1801), the architecture (1800) includes a plurality of transducers (1802), which are each individually addressed and optionally phase-matched as shown in insets (1803, 1804). FIG. 18a also shows TxRx drive, sense, tuning, control, and data processing circuitry (1805). In the configuration shown, the circuitry (1805) is electrically connected to the plurality of transducers (1802) with 64 signal lines (1806).

FIG. 18b shows a cross-section (1810) through line B-B in FIG. 18a, and a cross-section (1820) through line C-C in FIG. 18a. Both cross-sections (1810, 1820) show two transducers (1811, 1812). With respect to the legend (1811), the transducers include a graphene membrane (1813) mounted to silicon (1814). A metal layer (1815) is provided on a portion of the silicon (1814) to act as an electrode, and through-silicon vias (TSVs) (1816) are provided for electrical connection to the metal layer (1815). Both cross-sections show acoustic vent holes (1817), which pass through the silicon (1814) and metal layers (1815). The silicon (1814) shown in both cross-sections is formed of two wafers (1818, 1819). In cross-section (1820), there is an SiO₂ layer (1821) on the bottom side of wafer (1819). Several through-silicon vias (1816) pass through the SiO₂ layer (1821).

FIG. 18c depicts details related to the materials implementing this array architecture. FIG. 18c shows a graphene diaphragm (1831) and two metal layers (1832, 1833) electrically connected to the diaphragm. Adjacent to metal layers (1832, 1833) are first silicon wafers (1836, 1837) having dielectric layers (1834, 1835, 1838, 1839), e.g. SiO₂, on their top and bottom surfaces. Adjacent to the dielectric layers (1834, 1835) is bulk silicon wafer material (1836, 1837). Bonded to first silicon wafers (1836, 1837) are second silicon wafers (1840, 1841). Second silicon wafers also have dielectric layers (1842, 1843, 1844, 1845), e.g. SiO₂, on their top and bottom surfaces. Through-silicon vias (1846) pass through second wafers (1840, 1841) to electrically connect metal layers (1847, 1848, 1849, 1850). As shown on the right side, trenches (1851) may be provided to electrically isolate individual transducers. Acoustic vents (1852) are also provided. As shown, the two halves of the transducer (1830) are identical, and each half is fabricated from two wafers.

### Manufacturing

A multi-layer graphene membrane used as the diaphragm are successfully produced by chemical vapor deposition (CVD) using a Nickel foil as a growth catalyst at 11000 in a CH₄ and H₂ environment. When processed through CVD, the graphene grows on both sides of the foil, one side is removed, or etched, by a chemical ashing process. Then the other side is coated with a polymer film such as PMMA or other similar spin on polymers. This coating serves to provide structural strength to the graphene film during subsequent processing and is eventually charged at its Currie Temperature to obtain electret voltage. After this step, the Nickel film is removed chemically and the remaining film of graphene and PMMA are suspended to make a diaphragm.

In another process where the transducer diaphragm is composed only of graphene, the PMMA or other spin-on polymer is alternatively removed once the films has been suspended by using a solvent immersion. Then, another polymer films such as Teflon or other films can be coated either on one side or both sides of the graphene diaphragm by means of electron beam evaporation, vapor deposition or spin coating.

A common method used in charging electrets is thermal charging, which involves heating a material above its glass transition or Curie temperature under a strong electric field, followed by intense cooling, to “freeze” the dipoles, space charges, and real charges. Other commonly used methods to charge electrets are corona discharging, electron beam, or triboelectric charging. All these methods are used for this invention according to dielectric material properties such as dielectric breakdown and polarity. Choosing an electret charging method will additionally depend on dimensional properties of the dielectric including thickness and area.

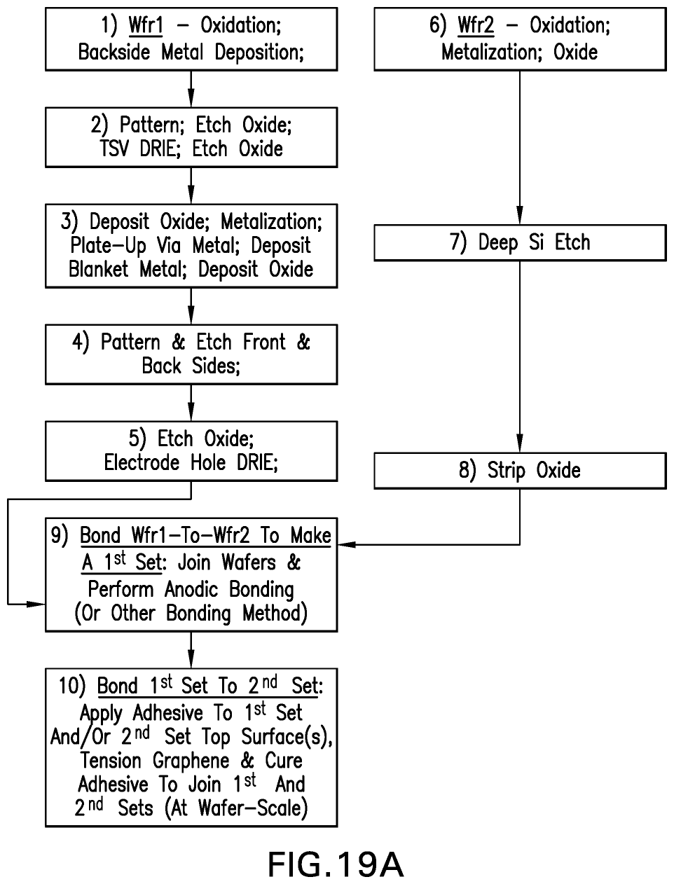

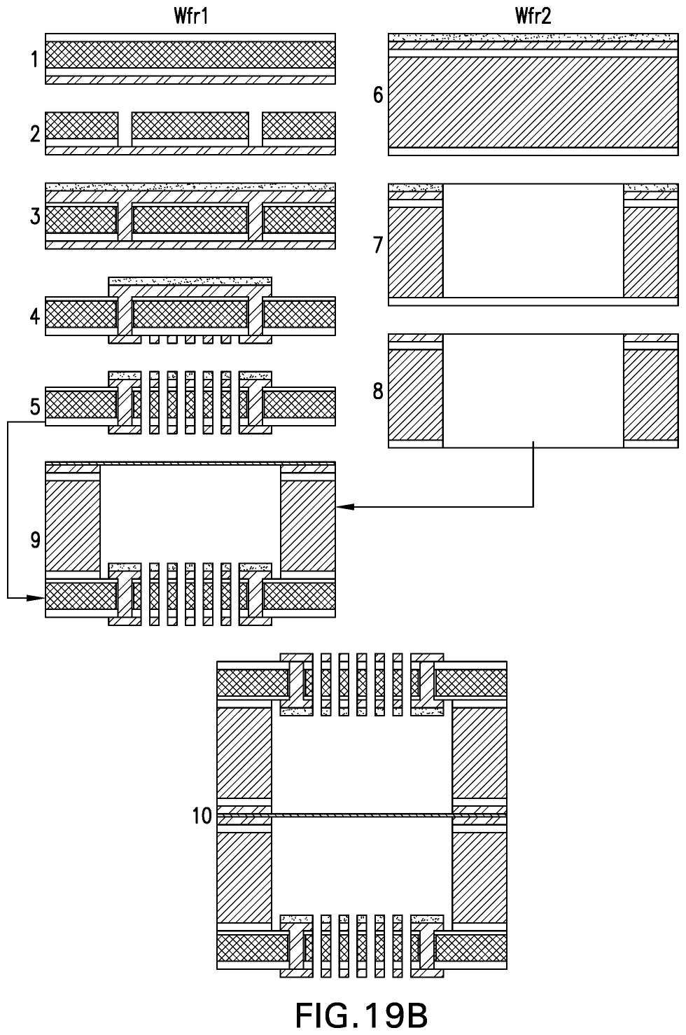

Embodiments of the present application may be manufactured using a MEMS-style approach. FIG. 19 depicts one embodiment of a manufacturing technique and/or method used to manufacture embodiments of the present application. In particular, FIG. 19 depicts fabrication involving two wafers: wafer 1 (Wfr1) and wafer 2 (Wfr 2).

FIGS. 19a and 19b depict an exemplary embodiment of a manufacturing method for manufacturing certain embodiments of the present application. In particular FIG. 19a shows the method steps which correlate to the intermediate constructions shown in FIG. 19b. With respect to FIG. 19b, the intermediate construction shown at step 9 is one half of the final construction shown at step 10.

As to wafer 1, the processing steps shown include: use wafer grinding and/or lapping with polishing to thin wafer 1 (Wfr1) to the desired (Spacer) thickness; grow thermal oxide; deposit metal and a sacrificial oxide; pattern and etch oxide and metal; deep Si etch to make transducer cavities. Those skilled in the art of microfabrication will recognize that a glass wafer can be used if desired instead of a silicon wafer to provide essentially the same final device architecture, where, in this case, glass wafer etching will be done using a different etch chemistry and a different etch mask material.

As to wafer 2, there are two options for processing, depending on the desired architecture. The processing steps needed to realize the architecture using through-silicon-vias (TS-Via) in Wfr2 are: Use wafer grinding, lapping and polishing to thin Wfr2 to the desired (Electrode) thickness; grow thermal oxide; deposit metal and a sacrificial oxide on both sides of the wafer; pattern and etch Wfr2 top-side oxide and metal layers; deep Si etch to make electrode holes; pattern and etch the oxide/metal layers on Wfr2 backside. In this case it is advantageous to use a lightly-doped, insulating Si wafer for Wfr2. Those skilled in the art of microfabrication will recognize that a glass wafer can be used if desired instead of a silicon wafer to provide essentially the same final device architecture, where, in this case, glass wafer etching will be done using a different etch chemistry and a different etch mask material.

Alternatively, wafer 2 can be processed with only one metal layer patterned on the backside. In this case, Wfr2 should be heavily-doped to provide a low-loss Si electrode material. In addition, the high conductivity of Wfr2 requires trench isolation to protect against short-circuits between adjacent transducers, as shown in the lower right drawing in FIG. 19.

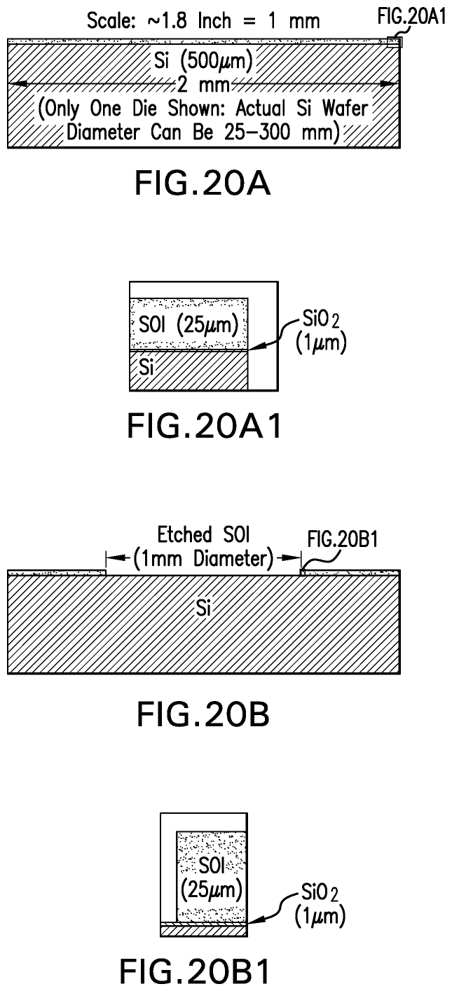

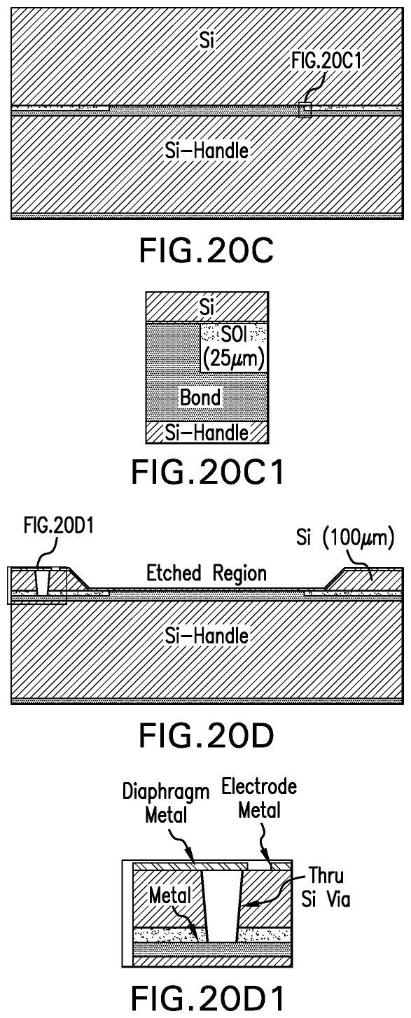

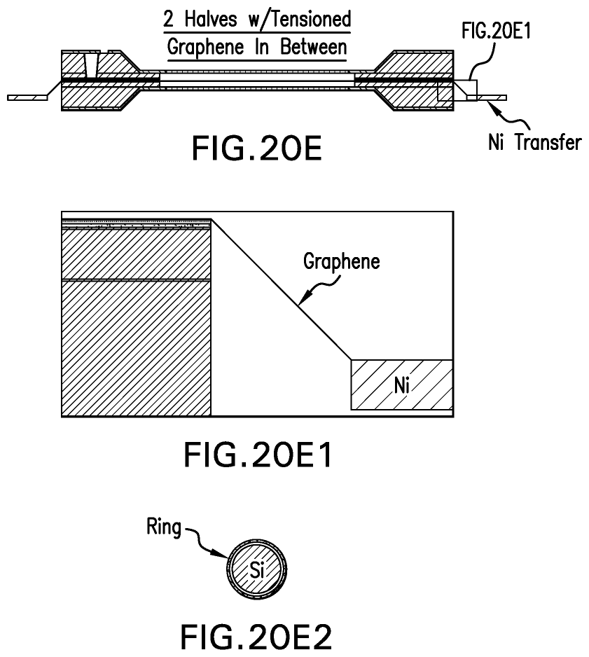

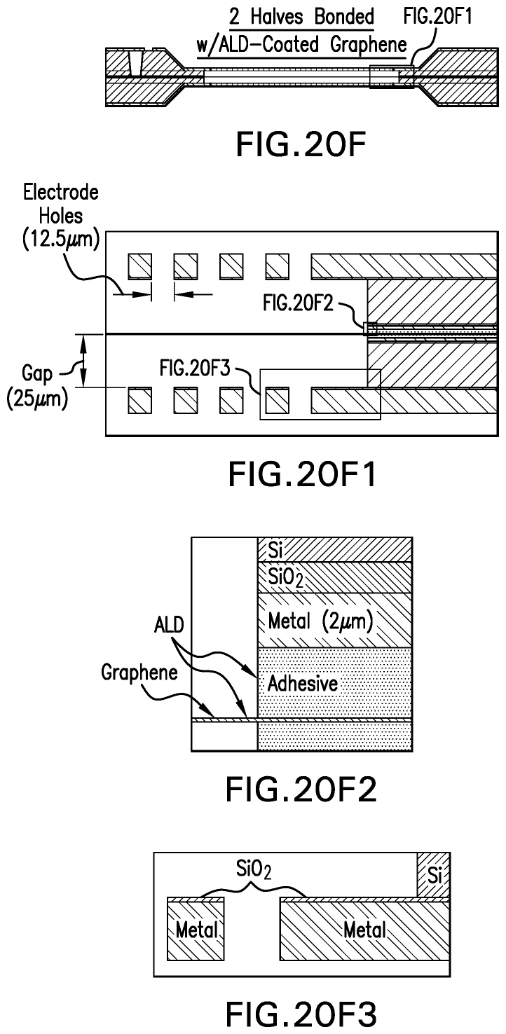

FIGS. 20A-E depict an exemplary embodiment of another manufacturing method for manufacturing certain embodiments of the present application.

In particular, FIG. 20A shows a to-scale (1.8 inch=1 mm) drawing of a second manufacturing approach utilizing an SOI wafer as the starting substrate. A 1 mm-diameter transducer is used in this example, although based on the disclosure of this application, a person of ordinary skill in the art would recognize other diameters are possible. In the example shown in FIG. 20A, only a single 2 mm-wide die is shown at each step for simplicity. The starting substrate is a 500 um-thick Si handle wafer with a 1 um-thick SiO₂ layer and a 25 um-thick SOI layer, as shown in FIG. 20A1. In this approach, the gap thickness is determined by the SOI thickness, which can be controlled by polishing the SOI layer to a precise target value.

FIG. 20B shows the results after depositing a top SiO₂ layer as a deep Si etch hardmask; and a deep Si etch to create a 1 mm-diameter opening through the SOI layer stopping on the SiO₂ layer underneath the SOI layer. FIG. 20B1 shows an enlarged portion of FIG. 20B at the corner of the opening in the SOI layer.

FIG. 20C shows the structure after flipping the SOI wafer over onto a (temporary) Si handle wafer and bonding the two together using a removable material, such as “Crystalbond 509,” a wax that provides a strong bond that does not degrade in mild solvents such as IPA but can be completely removed when separating the two wafer is desired using a stronger solvent such as acetone for example.

FIG. 20D shows the results after thinning the Si wafer to 100 um (for example); metallization, patterning, etching through the Si handle wafer, the 1 um SiO2 layer, and the 25 um SOI layer, stopping on the metal layer as shown in FIG. 20D1; following by pattern and crystallographic etch to remove the Si from over the central electrode region, where the crystallographic etch (of a Si 100 wafer) provides a sloped edge compatible with subsequence metal routing to the electrode region; followed metal deposition, pattern and etch to form the diaphragm and electrode interconnects.

FIG. 20E shows results after removal of the temporary Si handle wafer to give a fully-processed wafer representing one-half of a completed transducer. An epoxy or adhesive can then be applied to certain regions of the wafer surface in preparation for the subsequent graphene bonding steps. Two transducer halves are then positioned so that they are separated by a small distance with a graphene suspension stretched over the bottom wafer. Once the graphene is fully tensioned over the entire wafer (which can be done with wafers having diameters ranging from 25 to 300 mm), the two wafers are joined together to adhere the graphene to both top and bottom transducer halves.

In certain embodiments, it is important for the graphene diaphragm to have sufficient tension to avoid slackening of the diaphragm, which can create unwanted properties in certain embodiments. Note, in other embodiments, such as those employing collapse mode or collapse-snapback mode, the graphene diaphragm may not need a tensioning step. In the embodiment shown herein, tensioning can be performed using a graphene layer suspended on a Ni ring, as depicted in FIGS. 20E1 and 20E2. The Ni suspension ring is a straightforward part to fabricate given that the graphene is grown on a Ni substrate. For example, the SOI wafers can be 200 mm diameter and the graphene can be grown on 300 mm-diameter Ni substrates so that, once the suspension is formed using standard methods, the Ni ring will fit over the transducer wafer so that proper graphene tensioning can be done.

FIG. 20F shows the two transducer halves bonded together with the graphene suspension bonded in place. FIG. 20F1 is the enlarged area of FIG. 20F indicated. Electrode hoes of approximately 12.5 microns in size can be seen, with an electrode gap of 20 microns. The last step in the process flow is to deposit a thin mechanical support layer on top and bottom of the graphene suspension, as shown in FIG. 20F2, which is a further enlargement of FIG. 20F1. This layer can be deposited using atomic layer deposition (ALD) or vapor-phase deposition and can be diamond-like carbon (DLC), aluminum oxide (Al₂O₃), or organic materials such as PMMA, PEEK, or polyimide. FIG. 20F3 is also a further enlargement of FIG. 20F1 as indicated.

Additional details are shown in FIGS. 20F1, F2, F3. As listed in Table I, for the 1 mm-diameter example transducer as discussed in FIG. 20, electrode holes will be approximately 12.5 um in diameter, and the gap is approximately 25 um. The graphene layer is typically about 0.1 um thick. The ALD layer can be made as thick or thin as needed, but can be controlled to be as thin as approximately 0.05 um so that it adds minimal bulk and mass to the diaphragm while providing electrical insulation and adding mechanical strength.

The GMUT manufacturing approach described in FIG. 20 will yield well over 6000 (single-sided) 1 mm-diameter transducers (2 mm×2 mm die) from a single 200 mm-diameter Si wafer.

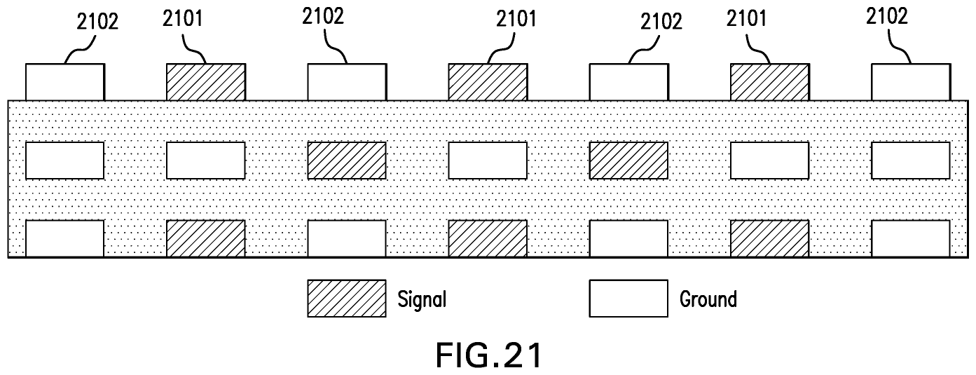

FIG. 21 shows an example of a general method that can be utilized within a GMUT array to eliminate or reduce cross-talk between signal lines. It uses a coaxial shielding approach where each signal line is shielded from other signal lines and external noise by adjacent ground lines. This is especially important when a large-area array is used (see FIG. 18) or when there are multiple, closely-spaced signal lines that require low-noise, superior transmission line signal quality.

FIG. 21 depicts an exemplary embodiment of an advanced transmission line shielding method for superior signal integrity. In particular, FIG. 21 shows an example of a general method that can be utilized within a GMUT array to eliminate or reduce cross-talk between signal lines. It uses a coaxial shielding approach where each signal line (2101) is shielded from other signal lines (2101) and external noise by adjacent ground lines (2102). This is especially important when a large-area array is used (see FIG. 18) or when there are multiple, closely-spaced signal lines that require low-noise, superior transmission line signal quality.

1. A micromachined ultrasonic transducer comprising:
a backing layer,
a spacer layer, and
a diaphragm comprising a material selected from the group consisting of graphene, h-BN, MoS2, and combinations thereof,
wherein the backing layer comprises a first etched semiconductor, glass, or polymer,
wherein the spacer layer comprises a second etched semiconductor, glass, or polymer.

2. The micromachined ultrasonic transducer of claim 1,
wherein the diaphragm comprises graphene.

3. The micromachined ultrasonic transducer of claim 1,
wherein the backing layer further comprises an electrode layer arranged on (a) the first etched semiconductor, glass, or polymer or (b) an oxide layer arranged on the first etched semiconductor, glass, polymer.

4. The micromachined ultrasonic transducer of claim 3,
wherein the electrode layer comprises a material selected from the group consisting of aluminum, copper, platinum, gold, iridium, tungsten, titanium, silver, palladium, metal alloys (TiW, TiN etc.), doped silicon, metal silicides (NiSi, PtSi, TiSi2, WSi2 etc.), indium tin oxide (ITO), fluorene doped tin oxide (FTO), doped zinc oxide, poly(3,4-ethylenedioxythiphene) (PEDOT) and its derivatives, carbon nanotubes, graphene, graphite, or conductive or semiconductive carbon.

5. The micromachined ultrasonic transducer of claim 1,
wherein the spacer layer further comprises a conductive layer arranged on (a) the second etched semiconductor, glass, or polymer or (b) an oxide layer arranged on the second etched semiconductor, glass, or polymer.

6. The micromachined ultrasonic transducer of claim 5,
wherein the electrode layer comprises a material selected from the group consisting of aluminum, copper, platinum, gold, iridium, tungsten, titanium, silver, palladium, metal alloys (TiW, TiN etc.), doped silicon, metal silicides (NiSi, PtSi, TiSi2, WSi2 etc.), indium tin oxide (ITO), fluorene doped tin oxide (FTO), doped zinc oxide, poly(3,4-ethylenedioxythiphene) (PEDOT) and its derivatives, carbon nanotubes, graphene, graphite, or conductive or semiconductive carbon.

7. The micromachined ultrasonic transducer of claim 1,
further comprising a second spacer layer and a top layer, wherein the second spacer layer comprises a third etched semiconductor, glass, polymer wherein the top layer comprises a fourth etched semiconductor or glass.

8. The micromachined ultrasonic transducer of claim 7,
wherein the backing layer or the top layer comprise acoustic holes extending through the entire backing layer or top layer.

9. The micromachined ultrasonic transducer of claim 8,
further comprising an acoustic matching material arranged over the acoustic holes to seal the device.

10. The micromachined ultrasonic transducer of claim 9,
wherein the acoustic matching material comprises graphene.

11. The micromachined ultrasonic transducer of claim 2,
wherein the diaphragm or the backing layer further comprises a dielectric material having a permanently embedded static electric dipole moment.

12. The micromachined ultrasonic transducer of claim 11,
wherein the dielectric material is selected from the group consisting of PTFE, perfluorinated dioxole, cycloolefin copolymer, BCB, PFCB, FEP, PFA, PVDF, VDF, PE, PP, PET, PI, PMMA, EVA, and copolymers thereof.

13. The micromachined ultrasonic transducer of claim 11,
wherein the dielectric material is selected from the group consisting of silicon dioxide, silicon nitride, aluminum oxide, titanium dioxide, glass, PZT, a transition metal oxide, graphene oxide, and combinations thereof.

14. A method of manufacturing a micromachined ultrasonic transducer, the method comprising:
providing a backing layer comprising a material selected from the group consisting of silicon, glass, and polymer,
providing a first conductive layer on the backing layer,
providing through-holes in the backing layer and the first conductive layer, providing a first spacer layer comprising a material selected from the group consisting of silicon, glass, and polymer,
providing a second conductive layer on the first spacer layer,
providing a central hole in the first spacer layer and the second conductive layer, and
permanently joining the backing layer, the first spacer layer, and a diaphragm comprising a material selected from the group consisting of graphene, h-BN, MoS2, and combinations thereof.

15. The method of claim 14,
wherein the diaphragm comprises graphene.

16. The method of claim 14,
wherein the backing layer and the spacer layer comprise silicon, wherein prior to providing the first and second conductive layers, the method further comprises providing a first oxide layer on the backing layer and a second oxide layer on the spacer layer, such that the first and second conductive layers are provided on the first and second oxide layers.

17. The method of claim 14, further comprising:
providing a top layer comprising a material selected from the group consisting of silicon, glass, and polymer,
providing a third conductive layer on the top layer,
providing through-holes in the top layer and the third conductive layer, providing a second spacer layer comprising a material selected from the group consisting of silicon, glass, and polymer,
providing a central hole in the second spacer material, and
permanently joining the backing layer, the first spacer layer, and the diaphragm with the second spacer layer and the top layer.

18. The method of claim 14,
wherein the diaphragm is electrically connected to the second conductive layer.

19. A method of operating a micromachined ultrasonic transducer, the method comprising:
providing a micromachined ultrasonic transducer comprising a backing layer, a spacer layer, and a diaphragm, wherein the diaphragm comprises a material selected from the group consisting of graphene, h-BN, MoS2, and combinations thereof, generating an electric field sufficient to move the diaphragm into physical contact with the backing layer.

20. The method of claim 19,
wherein the diaphragm comprises graphene.

21. The method of claim 19,
wherein the backing layer comprises an electrode with a dielectric layer configured to prevent the diaphragm and the electrode from creating a short circuit when the diaphragm moves into physical contact with the backing layer.

22. The method of claim 21, further comprising:
operating micromachined ultrasonic transducer while keeping the center of the diaphragm touching the dielectric layer.

23. The method of claim 21, further comprising:
operating the micromachined ultrasonic transducer in a manner involving the diaphragm repeatedly (a) touching the dielectric layer and (b) releasing such that the diaphragm is not touching the dielectric layer.

24. An array of transducers comprising:
a plurality of micromachined ultrasonic transducers, each micromachined ultrasonic transducer comprising a backing layer, a spacer layer, and a diaphragm, wherein the diaphragm comprises a material selected from the group consisting of graphene, h-BN, MoS2, and combinations thereof, and
metallic interconnects connecting each micromachined ultrasonic transducer to processing circuitry configured to drive or detect a response in each micromachined ultrasonic transducer.

25. The array of transducers of claim 24,
wherein the diaphragm comprises graphene.

26. The array of transducers of claim 24,
wherein all micromachined ultrasonic transducers are electrically addressed together.

27. The array of transducers of claim 24,
wherein each of the micromachined ultrasonic transducers is individually electrically addressed.

28. The array of transducers of claim 24,
wherein the metallic interconnects between the processing circuitry and the individual transducers have substantially the same wire length and impedance so that they also have substantially the same signal propagation time between processor and transducer.

29. A transducer comprising:
a graphene diaphragm;
a first electrode, and
a charged electret material applied to either the graphene diaphragm or the first electrode.

30. The transducer of claim 29,
further comprising a second electrode.

31. The transducer of claim 29,
wherein the electret material is applied to the graphene diaphragm.

32. The transducer of claim 30,
wherein the electret material is applied to the first or second electrode.

33. The transducer of claim 30,
wherein the electret material is selected from the group consisting of PTFE (e.g. TEFLON), perfluorinated dioxole (e.g. TEFLON AF), cycloolefin copolymer, BCB, PFCB, FEP, PFA, PVDF, VDF, PE, PP, PET, PI, PMMA, EVA, Polyetherimide (PEI or “Ultem”) and copolymers thereof.

34. The transducer of claim 30,
wherein the electret material is selected from the group consisting of silicon dioxide (e.g. Quartz), silicon nitride, aluminum oxide, titanium dioxide, glass, PZT, a transition metal oxide, graphene oxide, fluorine-doped silicon oxide (e.g. F-TEOS), hafnium dioxide, hafnium silicate, zirconium dioxide, and combinations thereof.

35. The transducer of claim 30,
wherein a voltage required to operate the transducer is less than a voltage required to operate a transducer in which the electret material is omitted.
